(19) United States
(12) Patent Application Publication
(10) Pub. No.: US 2025/0248099 A1
(43) Pub. Date: Jul. 31, 2025

(54) SEMICONDUCTOR DEVICE

(71) Applicant: Samsung Electronics Co., Ltd., Suwon-si (KR)

(72) Inventors: Yeonuk Kim, Suwon-si (KR); Yunho Kang, Suwon-si (KR); Minsik Kim, Suwon-si (KR); Seran Oh, Suwon-si (KR); Byounghoon Lee, Suwon-si (KR); Jangeun Lee, Suwon-si (KR)

(21) Appl. No.: 19/003,224

(22) Filed: Dec. 27, 2024

(30) Foreign Application Priority Data
Jan. 30, 2024 (KR) 10-2024-0013917

(51) Int. Cl. H10D 64/23; H10D 30/00; H10D 30/43; H10D 62/10; H10D 64/66

(52) U.S. Cl. CPC H10D 64/251; H10D 30/43; H10D 30/501; H10D 62/121; H10D 64/665

(57) ABSTRACT

Disclosed is a semiconductor device including a substrate and a wiring structure on the substrate. The wiring structure includes a first interlayer dielectric layer on the substrate and including a plurality of first metal lines, and a second interlayer dielectric layer on the first interlayer dielectric layer and including a via structure connected to the first metal line. The via structure includes a first via part and a second via part on the first via part. A first width of the first via part is less than a second width of the second via part.

### CROSS-REFERENCE TO RELATED APPLICATION

This U.S. nonprovisional application claims priority under 35 U.S.C § 119 to Korean Patent Application No. 10-2024-0013917 filed on Jan. 30, 2024 in the Korean Intellectual Property Office, the disclosure of which is hereby incorporated by reference in its entirety.

### BACKGROUND

The present inventive concepts relate to a semiconductor device, and more particularly, to a semiconductor device including a field effect transistor.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some embodiments of the present inventive concepts provide a semiconductor device with improved electrical properties.

Some embodiments of the present inventive concepts provide a semiconductor device with increased reliability.

According to some embodiments of the present inventive concepts, a semiconductor device may include a substrate, and a wiring structure on the substrate. The wiring structure may include a first interlayer dielectric layer, a first metal line that extends into the first interlayer dielectric layer, and a second interlayer dielectric layer on the first interlayer dielectric layer, a via structure that extends into the second interlayer dielectric layer and is connected to the first metal line. The via structure may include a first via part, and a second via part on the first via part. A first width of the first via part may be less than a second width of the second via part.

According to some embodiments of the present inventive concepts, a semiconductor device may include a substrate, a channel pattern on the substrate, a source/drain pattern electrically connected to the channel pattern, a gate electrode on the channel pattern, a first interlayer dielectric layer on the source/drain pattern, a second interlayer dielectric layer on the first interlayer dielectric layer and the gate electrode, an active contact that extends into the first and second interlayer dielectric layers and electrically connects with the source/drain pattern, a third interlayer dielectric layer on the second interlayer dielectric layer, a plurality of first metal lines extends into the third interlayer dielectric layer a first metal line of the first metal lines electrically connects to the active contact, and an air gap pattern is between adjacent ones of the plurality of first metal lines, and a fourth interlayer dielectric layer on the third interlayer dielectric layer, the fourth interlayer dielectric layer including a via structure that is electrically connected to a second one of the first metal lines. An uppermost surface of the air gap pattern a first distance from the substrate that is less than a second distance from a lowermost surface of the fourth interlayer dielectric layer to the substrate.

According to some embodiments of the present inventive concepts, a semiconductor device may include a substrate, a power delivery network layer on a bottom surface of the substrate, the power delivery network layer including a lower line, a plurality of source/drain patterns on the substrate, the source/drain patterns including a first pattern and a second pattern that are spaced apart from each other in a first direction, a channel pattern on a lateral surface of the source/drain pattern, the channel pattern including a plurality of semiconductor patterns that are stacked spaced apart from each other in a second direction that intersects the first direction, a gate electrode including a first inner electrode, a second inner electrode, and a third inner electrode between neighboring ones of the plurality of semiconductor patterns and an outer electrode on an uppermost one of the plurality of semiconductor patterns, a gate dielectric pattern on the gate electrode, a gate capping pattern on a top surface of the outer electrode, a first interlayer dielectric layer on the source/drain patterns, a second interlayer dielectric layer on the first interlayer dielectric layer and the gate capping pattern, an active contact that extends into the first and second interlayer dielectric layers and electrically connects with the second pattern of the source/drain pattern, a third interlayer dielectric layer on the second interlayer dielectric layer, the third interlayer dielectric layer including a first metal line electrically connected to the active contact, an adhesion pattern between the active contact and the first metal line, and an air gap pattern between adjacent ones of a plurality of first metal lines that comprises the first metal line, a fourth interlayer dielectric layer on the third interlayer dielectric layer, the fourth interlayer dielectric layer including a via structure electrically connected to a second metal line of the plurality of metal lines, a backside conductive structure that extends into the substrate and electrically connects the first pattern of the source/drain pattern to the power delivery network layer, and a lower dielectric pattern on the second pattern of the source/drain patterns. The via structure may include a first via part on the second metal line, and a second via part on the first via part. The second via part may have a tapered shape that extends away from the substrate.

### BRIEF DESCRIPTION OF DRAWINGS

FIG. 1 illustrates a plan view showing a semiconductor device according to some embodiments of the present inventive concepts.

FIGS. 2A, 2B, 2C, 2D, and 2E illustrate cross-sectional views respectively taken along lines A-A′, B-B′, C-C′, D-D′, and E-E′ of FIG. 1.

FIG. 3A illustrates an enlarged view showing section M of FIG. 2A.

FIG. 3B illustrates an enlarged view showing an example of FIG. 3A.

FIGS. 4A, 4B, 5A, 5B, 6A, 6B, 6C, 7A, 7B, 8, 9A, 9B, 10, 11A, 11B, 12A, 12B, 13, 14A, 14B, 15, 16A, 16B, 17, 18A, 18B, 19, 20A, 20B, 21A, 21B, 21C, 22A, 22B, 22C, 23A, and 23B illustrate diagrams showing a method of fabricating a semiconductor device according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts.

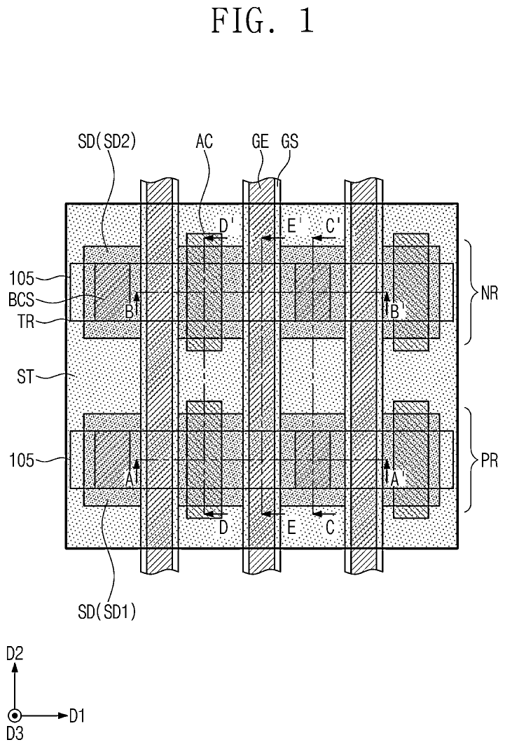

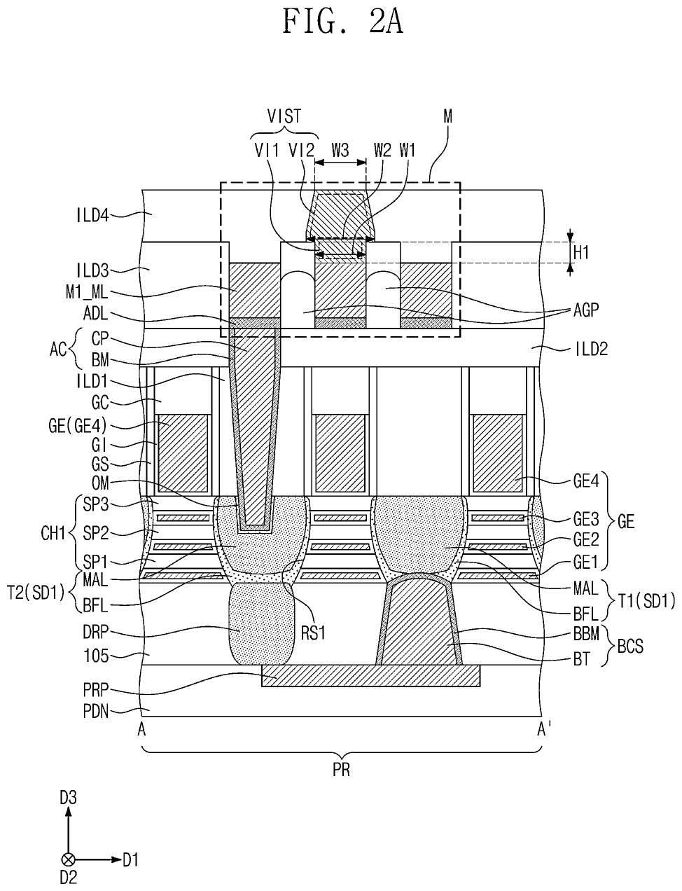

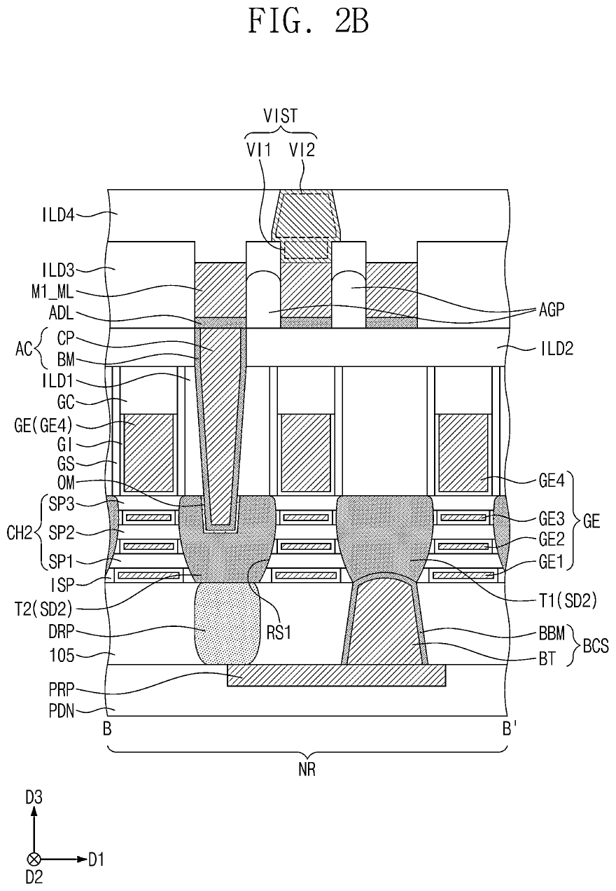

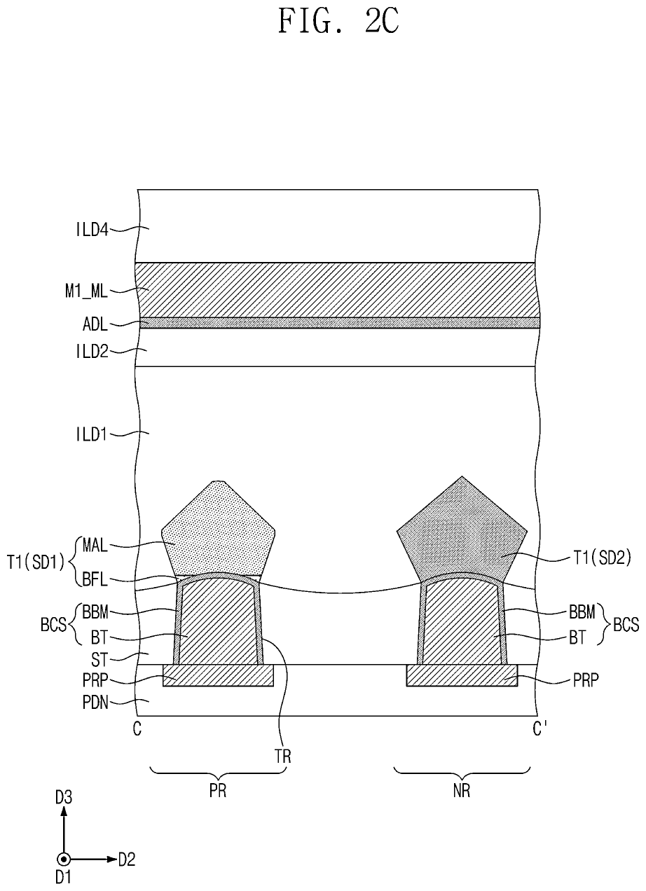

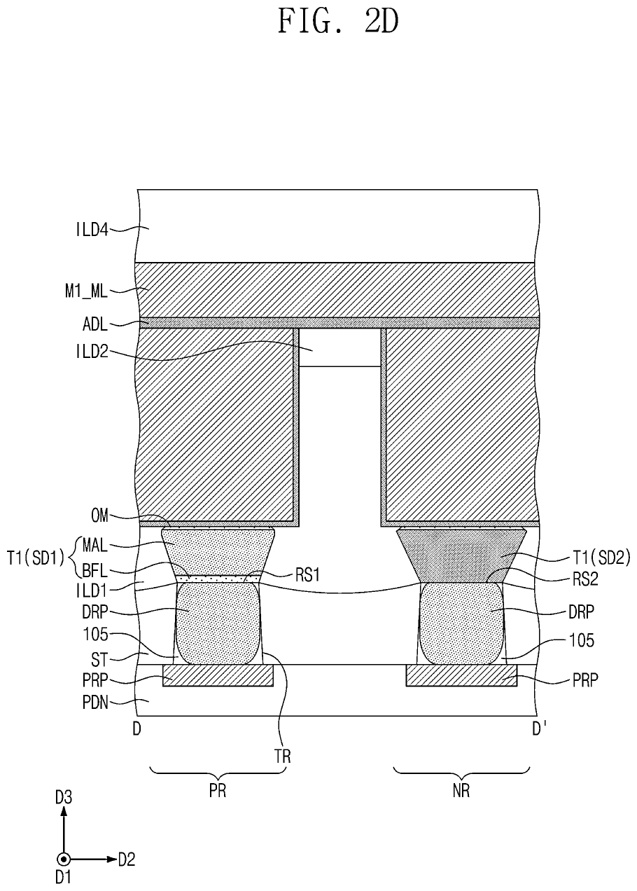

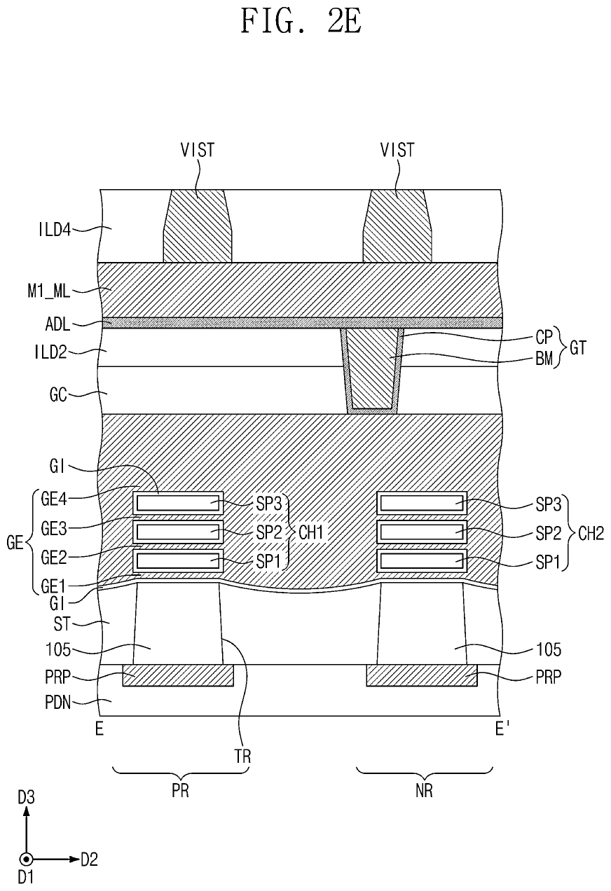

FIG. 1 illustrates a plan view showing a semiconductor device according to some embodiments of the present inventive concepts. FIGS. 2A, 2B, 2C, 2D, and 2E illustrate cross-sectional views respectively taken along lines A-A′, B-B′, C-C′, D-D′, and E-E′ of FIG. 1.

Referring to FIGS. 1 and 2A, 2B, 2C, 2D, and 2E, a substrate 105 may be provided to include a PMOSFET region PR and an NMOSFET region NR. The substrate 105 may include a silicon-based dielectric layer. For example, the substrate 105 may be a dielectric substrate. The substrate 105 may include at least one selected from a silicon oxide (SiO₂) layer, a silicon nitride (SiN) layer, and/or a silicon oxynitride (SiON) layer. In some embodiments, the substrate 105 may include a silicon layer. In this disclosure, each of the languages “A or B”, “at least one of A and B”, “at least one A or B”, “A, B, or C”, “at least one of A, B, and C”, and “at least one A, B, or C” may include one or any possible combination of elements listed in a corresponding one of the expressions mentioned above.

The PMOSFET region PR and the NMOSFET region NR may each extend in a first direction D1 and may be spaced apart from each other in a second direction D2. The first and second directions D1 and D2 may be parallel to a bottom surface of the substrate 105 and cross each other (e.g., orthogonal to each other).

A dielectric pattern may be defined by a trench TR of the substrate 105. When viewed in plan, the dielectric pattern may be a portion of the substrate 105. For example, the portion of the substrate 105 may protrude in a third direction D3. The third direction D3 may be perpendicular to the bottom surface of the substrate 105.

A device isolation pattern ST may be provided between the dielectric patterns, and the trench TR may be partially or completely filled with the device isolation pattern ST. The device isolation pattern ST may surround the dielectric patterns in plan view. The device isolation pattern ST may include a dielectric material. For example, the device isolation pattern ST may include silicon oxide (SiO₂).

A first channel pattern CH1 may be provided on the substrate 105 of the PMOSFET region PR, and a second channel pattern CH2 may be provided on the substrate 105 of the NMOSFET region NR. For example, the first channel pattern CH1 and the second channel pattern CH2 may be provided on the dielectric pattern. The first channel pattern CH1 may be provided in plural, and the plurality of first channel patterns CH1 may be spaced apart from each other in the first direction D1. The second channel pattern CH2 may be provided in plural, and the plurality of second channel patterns CH2 may be spaced apart from each other in the first direction D1. Each of the first and second channel patterns CH1 and CH2 may include a first semiconductor pattern SP1, a second semiconductor pattern SP2, and a third semiconductor pattern SP3 that neighbor each other in the third direction D3, but the present inventive concepts are not limited thereto. For example, each of the first and second channel patterns CH1 and CH2 may be provided in four or more. For example, each of the first, second, and third semiconductor patterns SP1, SP2, and SP3 may include crystalline silicon.

Subsequently described first recesses RS1 may be defined between the first channel patterns CH1 that neighbor each other in the first direction D1. Subsequently described second recesses RS2 may be defined between the second channel patterns CH2 that neighbor each other in the first direction D1.

A first source/drain pattern SD1 may be provided on the substrate 105 of the PMOSFET region PR, and the second source/drain pattern SD2 may be provided on the substrate 105 of the NMOSFET region NR. For example, the first source/drain pattern SD1 and the second source/drain pattern SD2 may be provided on the dielectric pattern. The first source/drain pattern SD1 may partially or completely fill the first recess RS1, and the second source/drain pattern SD2 may partially or completely fill the second recess RS2. Each of the first and second source/drain patterns SD1 and SD2 may be electrically connected to the first, second, and third semiconductor patterns SP1, SP2, and SP3. The first source/drain patterns SD1 may be impurity regions having a first conductivity type (e.g., p-type), and the second source/drain patterns SD2 may be impurity regions having a second conductivity type (e.g., n-type). For example, a pair of first source/drain patterns SD1 may be electrically connected through the first channel pattern CH1. A pair of second source/drain patterns SD2 may be electrically connected through the second channel pattern CH2.

The first source/drain patterns SD1 may include a semiconductor element (e.g., SiGe) whose lattice constant is greater than that of a semiconductor element of the first channel pattern CH1. Therefore, a pair of first source/drain patterns SD1 may provide the first channel pattern CH1 with a compressive stress. The second source/drain patterns SD2 may include the same semiconductor element (e.g., Si) as that of the second channel pattern CH2.

The first source/drain pattern SD1 may include a buffer layer BFL that covers, overlaps or is on an inner surface of the first recess RS1 and a main layer MAL that partially or completely fills most of a remaining unoccupied portion of the first recess RS1. For example, each of the buffer layer BFL and the main layer MAL may include silicon-germanium (SiGe). The buffer layer BFL may include germanium (Ge) whose concentration is relatively low. The main layer ML may include germanium (Ge) whose concentration is relatively high. In some embodiments, the buffer layer BFL may include only silicon (Si).

The first source/drain patterns SD1 and the second source/drain patterns SD2 may include a first pattern T1 electrically connected to a power delivery network layer PDN which will be discussed below and a second pattern T2 electrically connected to an active contact AC which will be discussed below.

A gate electrode GE may be provided on and/or run across the first and second channel patterns CH1 and CH2. The gate electrode GE may be provided in plural. The gate electrodes GE may each extend in the second direction D2, and may be spaced apart from each other in the first direction D1.

The gate electrode GE may include inner electrodes GE1, GE2, and GE3 and an outer electrode GE4. The inner electrodes GE1, GE2, and GE3 of the gate electrode GE may be provided between the substrate 105 and an uppermost one of a plurality of semiconductor patterns SP1, SP2, and SP3. The outer electrode GE4 of the gate electrode GE may be provided on the uppermost semiconductor pattern. The inner electrodes GE1, GE2, and GE3 of the gate electrode GE may include a first inner electrode GE1, a second inner electrode GE2, and a third inner electrode GE3, but the present inventive concepts are not limited thereto. In some embodiments, the gate electrode GE may include four or more inner electrodes. The first inner electrode GE1 may be interposed between the substrate 105 and the first semiconductor pattern SP1. The second inner electrode GE2 may be interposed between the first semiconductor pattern SP1 and the second semiconductor pattern SP2. The third inner electrode GE3 may be interposed between the second semiconductor pattern SP2 and the third semiconductor pattern SP3. The outer electrode GE4 of the gate electrode GE may be provided on the third semiconductor pattern SP3.

The gate electrode GE may include a first metal pattern and a second metal pattern on the first metal pattern. The first metal pattern may include a work-function metal that controls a threshold voltage of a transistor. For example, the first metal pattern may include at least one selected from metallic materials (e.g., Ti, Mo, W, Cu, Al, Ta, Ru, Ir, or Co) and metal nitrides (e.g., nitride of Ti, Mo, W, Cu, Al, Ta, Ru, Ir, or Co). The first metal pattern may further include carbon (C). The first metal pattern may include metallic materials having different work-function materials from each other.

The second metal pattern may include a metallic material (e.g., Ti, Mo, W, Cu, Al, Ta, Ru, Ir, or Co) whose resistance is less than that of the first metal pattern.

The first, second, and third inner electrodes GE1, GE2, and GE3 of the gate electrode GE may include a first metal pattern. The outer electrode GE4 of the gate electrode GE may include a first metal pattern and a second metal pattern.

A gate capping pattern GC may be provided on a top surface of the gate electrode GE. The gate capping pattern GC may be provided on the outer electrode GE4 of the gate electrode GE. For example, the gate capping pattern GC may include at least one selected from SiON, SiCN, SiCON, and/or SiN.

Gate spacers GS may be provided on lateral surfaces of the outer electrode GE4 of the gate electrode GE, and may extend onto lateral surfaces of the gate capping pattern GC. The gate spacer GS may include a single layer or a composite layer. For example, the gate spacer GS may include at least one selected from SiON, SiCN, SiCON, and/or SiN.

A gate dielectric pattern GI may be interposed between the gate electrode GE and each of the first, second, and third semiconductor patterns SP1, SP2, and SP3. The gate dielectric pattern GI may surround a top surface, a bottom surface, and opposite lateral surfaces of each of the first, second, and third semiconductor patterns SP1, SP2, and SP3. The gate dielectric pattern GI may cover, overlap, or be on a top surface of the device isolation pattern ST underneath the gate electrode GE. The gate dielectric pattern GI may be interposed between the outer electrode GE4 and the gate spacer GS. For example, the gate dielectric pattern GI may include at least one selected from silicon oxide (SiO₂), silicon oxynitride (SiON), and/or high-k dielectric materials. In this disclosure, the high-k dielectric material may be defined to indicate a material whose dielectric constant is greater than that of silicon oxide.

Referring to FIG. 2B, an inner spacer ISP may be interposed between the second source/drain pattern SD2 and a lateral surface of the gate electrode GE. The inner spacer ISP may be interposed between the second source/drain pattern SD2 and the first, second, and third inner electrodes GE1, GE2, and GE3. The inner spacer ISP may include a dielectric material. For example, the dielectric material may include at least one selected from silicon oxide, silicon nitride, and/or silicon oxynitride.

A first interlayer dielectric layer ILD1 may be provided on the substrate 105. The first interlayer dielectric layer ILD1 may cover, overlap, or be on the gate spacers GS and the first and second source/drain patterns SD1 and SD2. The first interlayer dielectric layer ILD1 may have a top surface located at a level substantially the same as that of that of the gate capping pattern GC and that of a top surface of the gate spacer GS.

The first interlayer dielectric layer ILD1 may be provided thereon with a second interlayer dielectric layer ILD2 that covers, overlaps, or is on the gate capping pattern GC. A third interlayer dielectric layer ILD3 may be provided on the second interlayer dielectric layer ILD2. A fourth interlayer dielectric layer ILD4 may be provided on the third interlayer dielectric layer ILD3. For example, the first, second, third, and fourth interlayer dielectric layers ILD1, ILD2, ILD3, and ILD4 may include silicon oxide (SiO₂).

An active contact AC may penetrate or extend into along the third direction D3 through the first and second interlayer dielectric layers ILD1 and ILD2. The active contact AC may be provided in plural, and lower portions of the plurality of active contacts AC may be buried in upper portions of the second patterns T2 of the first and second source/drain patterns SD1 and SD2. In this sense, the active contact AC may be a contact formed from a front surface of the substrate 105.

The active contact AC may include a conductive pattern CP that penetrates or extends into the first and second interlayer dielectric layers ILD1 and ILD2 and a barrier pattern BM that surrounds the conductive pattern CP. For example, the conductive pattern CP may include a metallic material (e.g., Ti, Mo, W, Cu, Al, Ta, Ru, Ir, or Co). The barrier pattern BM may include a metal nitride (e.g., nitride of one or more of Ti, Mo, W, Cu, Al, Ta, Ru, Ir, or Co).

An ohmic pattern OM may be interposed between the active contact AC and the second pattern T2 of the source/drain pattern SD1 or SD2. Thus, there may be an improvement in contact resistance between the active contact AC and the second pattern T2 of the source/drain pattern SD1 or SD2. For example, the ohmic pattern OM may include a metal silicide (e.g., silicide of Ti, Mo, W, Cu, Al, Ta, Ru, or Ir).

A first metal line M1_ML may be provided on the third interlayer dielectric layer ILD3. An adhesion pattern ADL may be interposed between the first metal line M1_ML and the second interlayer dielectric layer ILD2. The adhesion pattern ADL may be interposed between the first metal line M1_ML and the active contact AC. The first metal line M1_ML may be electrically connected through the contact pattern ADL to the active contact AC. A gate contact GT may be connected to the gate electrode GE, and the first metal line M1_ML may be electrically connected through the adhesion pattern ADL to the gate contact GT. Although not shown, each of the first metal line M1_ML and the adhesion pattern ADL may be provided in plural. The first metal lines M1_ML and the adhesion pattern ADL may include a metallic material (e.g., Ti, Mo, W, Cu, Al, Ta, Ru, Ir, or Co). For example, the first metal lines M1_ML may include Ru. In some embodiments, the first metal lines M1_ML may include Ru, Rh, Ir, Mo, Cu, Co, W, RuAl, NiAl, NbB₂, MoB₂, MoW, or any combination thereof.

An air gap pattern AGP may be interposed between a plurality of first metal lines M1_ML. The air gap pattern AGP may be surrounded by the first metal lines M1_ML, the second interlayer dielectric layer ILD2, and the third interlayer dielectric layer ILD3. For example, the air gap pattern AGP may be a void or a seam. The air gap pattern AGP may have an uppermost surface located at a level lower than that of uppermost surfaces of the first metal lines M1_ML. The uppermost surface of the air gap pattern AGP may be located at a level lower than that of a lowermost surface of the fourth interlayer dielectric layer ILD4.

A via structure VIST may be provided in the fourth interlayer dielectric layer ILD4. The via structure VIST may include a first via part VI1 and a second via part VI2 on the first via part VI1. The first via part VI1 may be a portion recessed toward the third interlayer dielectric layer ILD3. The first via part VI1 may be in direct contact with and electrically connected to the first metal line M1_ML. The second via part VI2 may have a tapered shape that is vertically upwards (e.g., in the third direction D3) from the substrate 105. The second via part VI2 may vertically overlap the first via part VI and portions of the air gap pattern AGP. The via structure VIST may include a metallic material (e.g., Ti, Mo, W, Cu, Al, Ta, Ru, Ir, or Co). For example, the via structure VIST may include Ru. In some embodiments, the via structure VIST may include Ru, Rh, Ir, Mo, Cu, Co, W, RuAl, NiAl, NbB₂, MoB₂, MoW, or any combination thereof.

A power delivery network layer PDN may be provided on the bottom surface of the substrate 105. The power delivery network layer PDN may include a plurality of lower lines PRP electrically connected to the source/drain patterns SD1 and SD2 through a backside conductive structure BCS which will be discussed below. The power delivery network layer PDN may include a wiring line network for applying a source voltage. The power delivery network layer PDN may include a wiring line network for applying a drain voltage.

A backside conductive structure BCS may be provided in the substrate 105. The backside conductive structure BCS may penetrate or extend into the substrate 105 and may be interposed between the power delivery network layer PDN and the first pattern T1 of the source/drain pattern SD1 or SD2. The backside conductive structure BCS may electrically connect the power delivery network layer PDN to the first pattern T1 of the source/drain pattern SD1 or SD2. Unlike the active contact AC discussed above, the backside conductive structure BCS may be a backside active contact formed from the bottom surface of the substrate 105.

The backside conductive structure BCS may have a bottom surface in direct contact with the lower line PRP of the power delivery network layer PDN. The backside conductive structure BCS may have a top surface in direct contact with the first pattern T1 of the source/drain pattern SD1 or SD2. The top surface of the backside conductive structure BCS may be curved convexly toward the first pattern T1. A width in the first direction D1 of the backside conductive structure BCS may decrease with decreasing distance from the first pattern T1.

The backside conductive structure BCS may include a backside conductive pattern BT and a backside barrier pattern BBM that surrounds the backside conductive pattern BT. For example, the backside conductive pattern BT may include a metallic material (e.g., Ti, Mo, W, Cu, Al, Ta, Ru, Ir, or Co). The backside barrier pattern BBM may include metal nitride (e.g., nitride of one or more of Ti, Mo, W, Cu, Al, Ta, Ru, Ir, or Co).

A lower dielectric pattern DRP may be provided in the substrate 105. For example, the lower dielectric pattern DRP may be buried in the substrate 105. The lower dielectric pattern DRP may be provided underneath the second pattern T2 of the source/drain pattern SD1 or SD2. The second pattern T2 of the source/drain pattern SD1 or SD2 may vertically overlap or contact the lower dielectric pattern DRP.

The lower dielectric pattern DRP may be in direct contact with the lower line PRP of the power delivery network layer PDN. The lower dielectric pattern DRP may be in direct contact with a portion of the lower line PRP. The lower dielectric pattern DRP may have a bottom surface in direct contact with the lower line PRP of the power delivery network layer PDN. The bottom surface of the lower dielectric pattern DRP may be located at a level substantially the same as that of the bottom surface of the backside conductive structure BCS. For example, the lower dielectric pattern DRP and the backside conductive structure BCS may have their bottom surfaces that are substantially coplanar with each other. The lower dielectric pattern DRP may have a curved surface at opposite sidewalls thereof. The opposite sidewalls may each have a convex shape toward the substrate 105.

An uppermost surface of the lower dielectric pattern DRP may be located at a level lower than an uppermost surface of the backside conductive structure BCS. In some embodiments, the lower dielectric pattern DRP and the backside conductive structure BCS may have their uppermost surfaces located at the same level. The uppermost surface of the lower dielectric pattern DRP may be located at the same level as that of a bottom surface of the gate dielectric pattern GI that surrounds the first inner electrode GE1. The uppermost surface of the backside conductive structure BCS may be located at a level higher than that of the bottom surface of the gate dielectric pattern GI and lower than that of a top surface of the gate dielectric pattern GI.

The lower dielectric pattern DRP may include a dielectric material different from that of the substrate 105. In some embodiments, the lower dielectric pattern DRP and the substrate 105 may include the same dielectric material. The lower dielectric pattern DRP may include at least one selected from a silicon oxide (SiO₂) layer, a silicon nitride (SiN) layer, an aluminum oxide (Al₂O₃) layer, and/or an aluminum nitride (AlN) layer. As discussed above, the substrate 105 may include at least one selected from a silicon oxide (SiO₂) layer, a silicon nitride (SiN) layer, and/or a silicon oxynitride (SiON) layer.

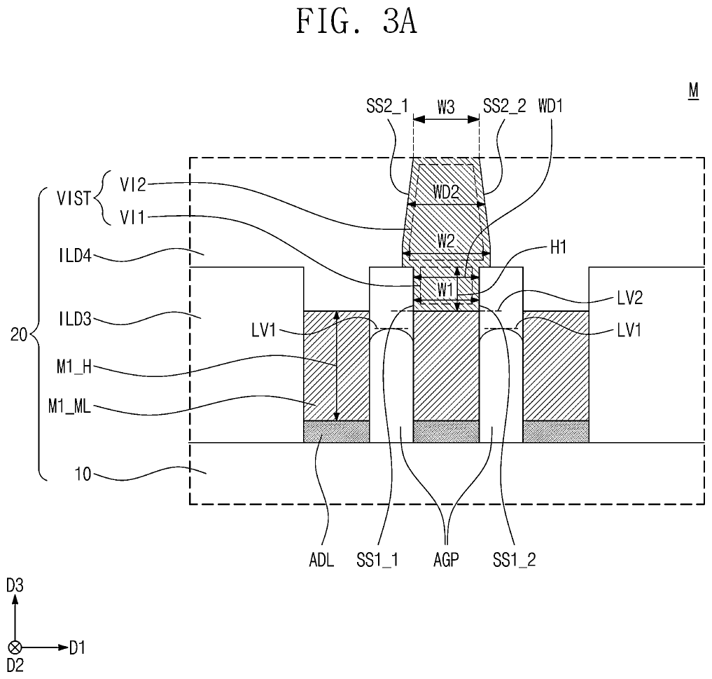

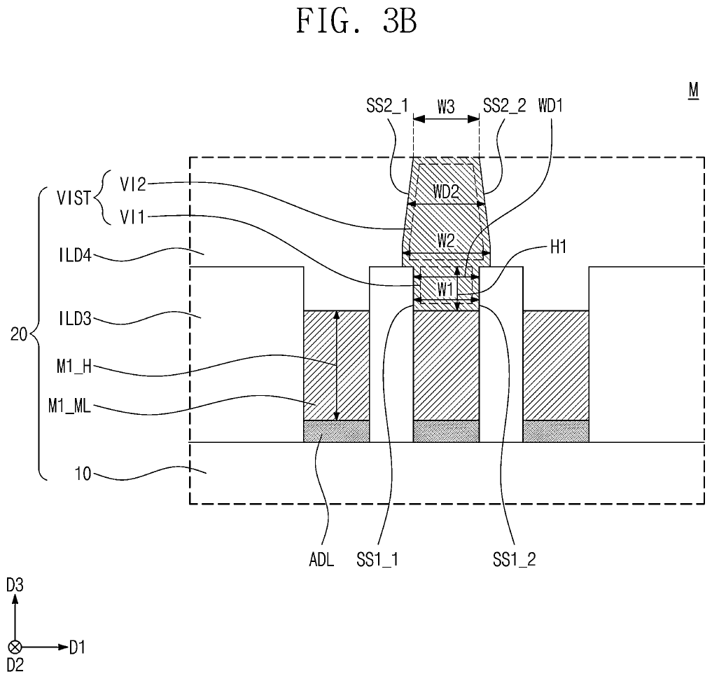

With reference to FIGS. 3A and 3B, the following will describe a wiring structure 20 according to some embodiments of the present inventive concepts. For brevity of description, an explanation of components repetitive to those discussed above will be omitted, and a difference thereof will be discussed in detail.

FIG. 3A illustrates an enlarged view showing section M of FIG. 2A. FIG. 3B illustrates an enlarged view showing an example of FIG. 3A.

After front-end-of-line (FEOL) and middle-end-of-line (MOL) processes are terminated, a formed transistor or structure may be defined as a cell structure 10. The cell structure 10 may include the power delivery network layer PDN discussed above, the substrate 105, a transistor on the PMOSFET region PR or the NMOSFET region NR, and the active contacts AC or the gate contact GT connected to the transistor. The cell structure 10 may include components discussed with reference to FIGS. 1, 2A, 2B, 2C, 2D, and 2E. In some embodiments, the cell structure 10 may be defined to include a structure formed after performing a front-end-of-line (FEOL) process, a middle-end-of-line (MOL) process, and a portion of a back-end-of-line (BEOL) process.

Referring to FIG. 3A, the wiring structure 20 may be provided on the cell structure 10. The wiring structure 20 may include the third interlayer dielectric layer ILD3, the adhesion pattern ADL, the first metal lines M1_ML, the air gap pattern AGP, the fourth interlayer dielectric layer ILD4, and the via structure VIST. The via structure VIST may be electrically connected to at least one of a plurality of first metal lines M1_ML. The lowermost surface of the fourth interlayer dielectric layer ILD4 may be located at a level in the third direction D3 lower than that of an uppermost surface of the third interlayer dielectric layer ILD3.

The via structure VIST may include a first via part VI1 and a second via part VI2 on the first via part VI1. The first via part VI1 may have a first width WD1 in the first direction D1, and the second via part VI2 may have a second width WD2 in the first direction D1. The first width WD1 may be defined to refer to a horizontal distance between a first sidewall SS1_1 and a second sidewall SS1_2 of the first via part VI1. The second width WD2 may be defined to refer to a horizontal distance between a third sidewall SS2_1 and a fourth sidewall SS2_2 of the second via part VI2.

The first sidewall SS1_1 and the second sidewall SS1_2 of the first via part VI1 may face each other in the first direction D1. The first and second sidewalls SS1_1 and SS1_2 may be aligned in the third direction D3. The first and second sidewalls SS1_1 and SS1_2 may be vertically aligned with corresponding sidewalls of the first metal line M1_ML. Thus, the first width WD1 may have a constant value. The first width WD1 may be the same as a width in the first direction D1 of the first metal line M1_ML.

The third sidewall SS2_1 and the fourth sidewall SS2_2 of the second via part VI2 may face each other in the first direction D1. The third sidewall SS2_1 may have a positive slope. The fourth sidewall SS2_2 may have a negative slope. Thus, the second width WD2 may gradually decrease in the third direction D3 perpendicular to the substrate 105. The second width WD2 may be greater than or equal to the first width WD1. In some embodiments, the third sidewall SS2_1 may become vertically aligned in the third direction D3 and then have a positive slope. The fourth sidewall SS2_2 may become vertically aligned in the third direction D3 and then have a negative slope.

The first via part VI1 may have a first line-width W1 in the first direction D1. When viewed in plan, the first line-width W1 may be defined to refer to a critical dimension (CD) value of the first via part VI1. The first line-width W1 may have a constant value. For example, the first width WD1 may be the same as the first line-width W1.

The second via part VI2 may have a second line-width W2 and a third line-width W3 in the first direction D1. When viewed in plan, the second line-width W2 may be defined to refer to a CD value of a lower portion of the second via part VI2. When viewed in plan, the third line-width W3 may be defined to refer to a CD value of an upper portion of the second via part VI2. For example, a maximum value of the second width WD2 may be the same as the second line-width W2, and a minimum value of the second width WD2 may be the same as the third line-width W3. The second line-width W2 may be greater than the third line-width W3. The third line-width W3 may be greater than the first line-width W1.

The first via part VI1 may have a first height H1 in the third direction D3. The first height H1 may be defined to refer to a vertical distance from a top surface of the first metal line M1_ML to the uppermost surface of the third interlayer dielectric layer ILD3. For example, the first height H1 may range from about 2 nm to about 9 nm. The first metal line M1_ML may have a second height M1_H in the third direction D3. The second height M1_H may be defined to refer to a vertical distance from a top surface of the adhesion pattern ADL to the lowermost surface of the fourth interlayer dielectric layer ILD4. The second height M1_H may be greater than the first height H1.

The first metal line M1_ML and the via structure VIST may include a metallic material, for example, Ru. As the first metal line M1_ML is formed by performing a physical vapor deposition (PVD) process and the via structure VIST is formed by performing a chemical vapor deposition (CVD) process in a subsequent fabrication process, an interface may be included between the first metal line M1_ML and the via structure VIST. The presence of the interface may be caused by the fact that the first metal line M1_ML and the via structure VIST have different grain directions from each other.

An uppermost surface of the air gap pattern AGP may be located at a first level LV1 in the third direction D3. A lowermost surface of the via structure VIST may be located at a second level LV2 in the third direction D3. The second level LV2 may be higher than the first level LV1. The lowermost surface of the fourth interlayer dielectric layer ILD4 may be located as the second level LV2. For example, a top surface of the air gap pattern AGP may be located at a lower level than that of the lowermost surface of the fourth interlayer dielectric layer ILD4, that of the top surface of the first metal line M1_ML, and that of the lowermost surface of the via structure VIST.

The air gap pattern AGP may have a height less than a sum of the second height M1_H and a height of the adhesion pattern ADL. In some embodiments, the air gap pattern AGP may have a height the same as or greater than the second height M1_H.

Referring to FIG. 3B, the air gap pattern AGP may not be interposed between the first metal lines M1_ML. For example, the third interlayer dielectric layer ILD3 may not include the air gap pattern AGP. The third interlayer dielectric layer ILD3 may include the first metal lines M1_ML therein.

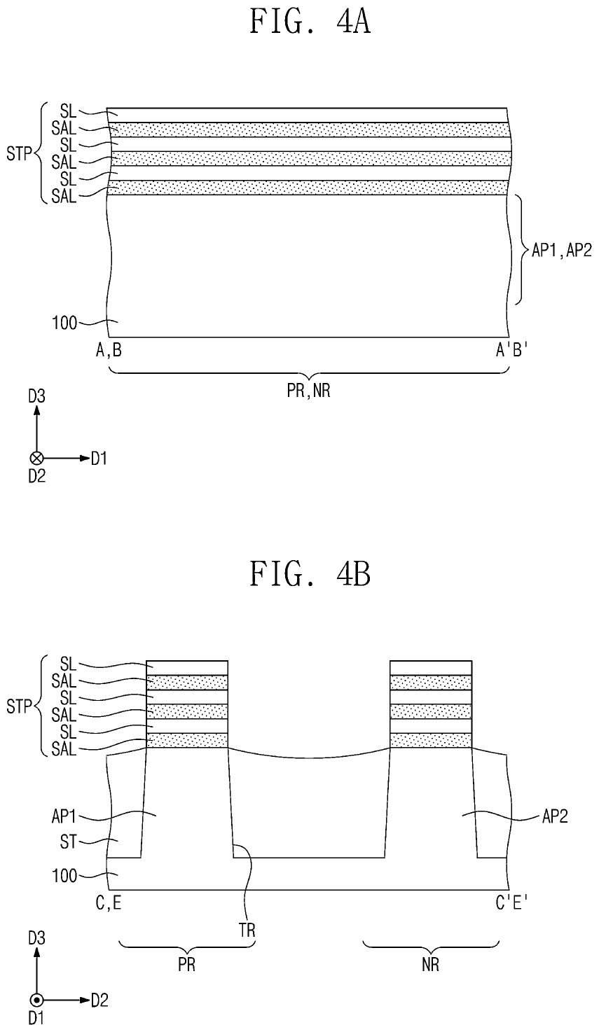

FIGS. 4A, 4B, 5A, 5B, 6A, 6B, 6C, 7A, 7B, 8, 9A, 9B, 10, 11A, 11B, 12A, 12B, 13, 14A, 14B, 15, 16A, 16B, 17, 18A, 18B, 19, 20A, 20B, 21A, 21B, 21C, 22A, 22B, 22C, 23A, and 23B illustrate diagrams showing a method of fabricating a semiconductor device according to some embodiments of the present inventive concepts.

Referring to FIGS. 1, 4A, and 4B, a semiconductor substrate 100 may be provided to include a PMOSFET region PR and an NMOSFET region NR. For example, the semiconductor substrate 100 may be a semiconductor substrate including a semiconductor material, such as a monocrystalline silicon substrate, a silicon-germanium substrate, or silicon-on-insulator (SOI) substrate. Stack patterns STP may be formed on the PMOSFET region PR and the NMOSFET region NR. For example, the formation of the stack patterns STP may include alternately stacking semiconductor layers SL and active layers SAL on the semiconductor substrate 100, forming mask patterns (not shown) that extend in a first direction D1, and using the mask patterns as an etching mask to perform a patterning process. In the patterning process, a portion of the semiconductor substrate 100 may be removed, and trenches TR may be formed to define a first active pattern AP1 and a second active pattern AP2.

The first active pattern AP1 may be formed on the PMOSFET region PR, and the second active pattern AP2 may be formed on the NMOSFET region NR. The first and second active patterns AP1 and AP2 may extend in the first direction D1. Device isolation patterns ST may be formed to partially or completely fill the trenches TR.

The sacrificial layers SAL may include a material having an etch selectivity with respect to the semiconductor layers SL. Thus, even when the sacrificial layers SAL are removed in a process which will be discussed below, the semiconductor layers SL may not be removed or may be slightly removed. For example, the semiconductor layers SL may include one of silicon (Si), germanium (Ge), and/or silicon-germanium (SiGe), and the sacrificial layers SAL may include another of silicon (Si), germanium (Ge), and/or silicon-germanium (SiGe).

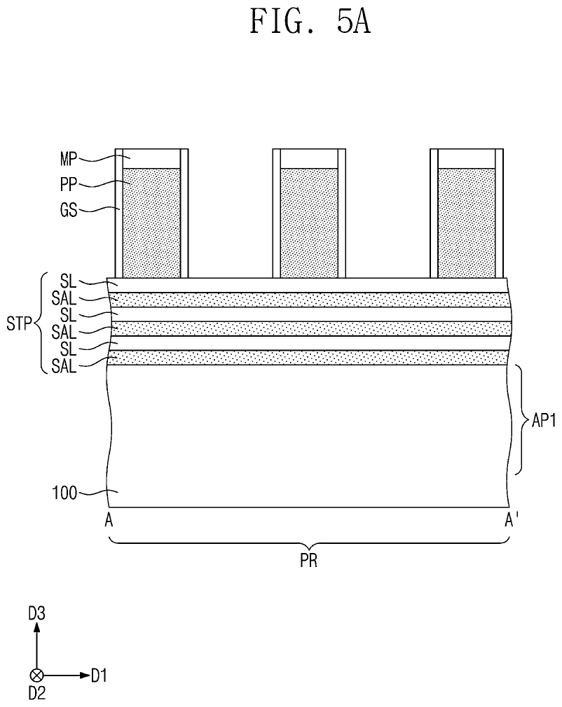

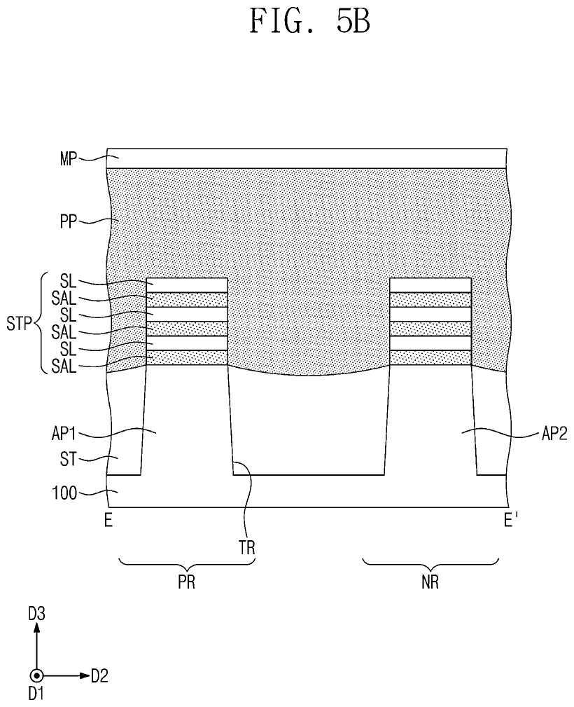

Referring to FIGS. 1, 5A, and 5B, sacrificial patterns PP may be formed to extend along a second direction D2 on the semiconductor substrate 100. The sacrificial patterns PP may be formed to cover, overlap, or be on top surfaces of the device isolation patterns ST and lateral and top surfaces of the stack patterns STP. For example, the formation of the sacrificial patterns PP may include forming a sacrificial layer (not shown) on the semiconductor substrate 100, forming hardmask patterns MP on the sacrificial layer, and using the hardmask patterns MP as an etching mask to remove a portion of the sacrificial layer to form the sacrificial patterns PP. For example, the sacrificial pattern PP may include polysilicon. Afterwards, gate spacers GS may be formed on lateral surfaces of the sacrificial patterns PP.

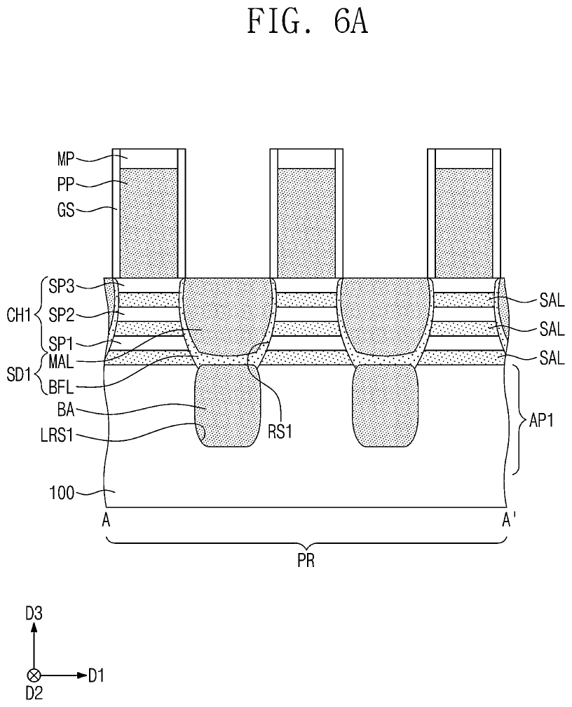

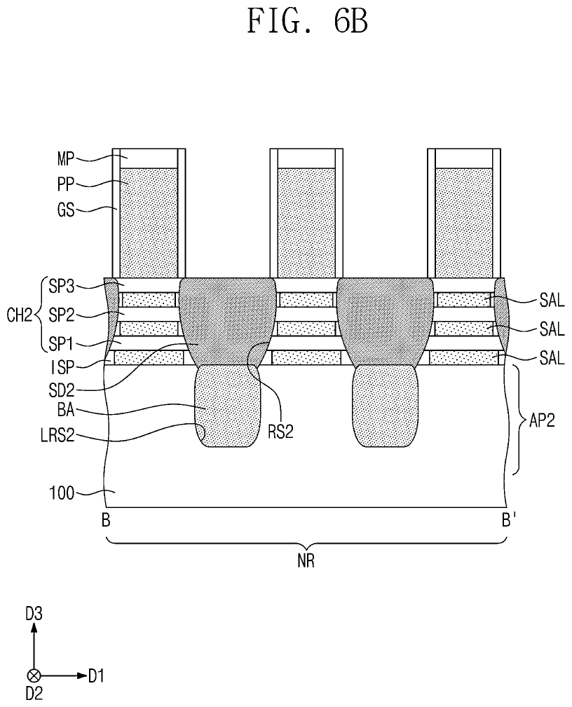

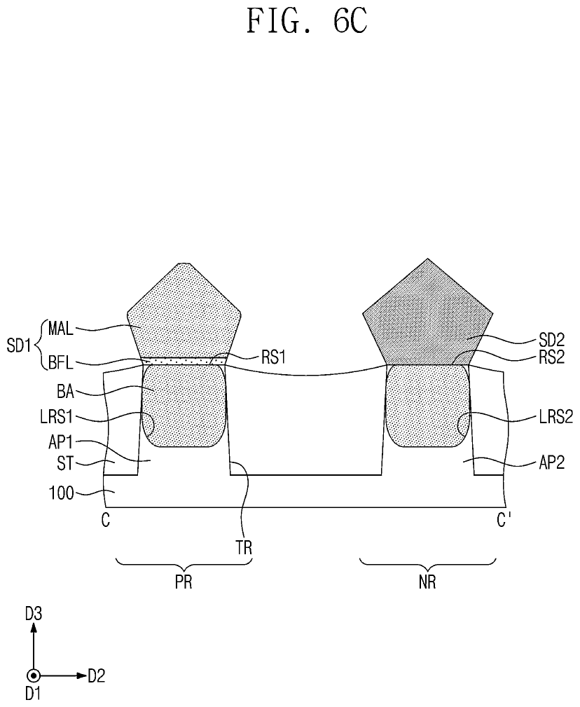

Referring to FIGS. 1, 6A, 6B, and 6C, first recesses RS1 may be formed in the stack pattern STP on the first active pattern AP1. Second recesses RS2 may be formed in the stack pattern STP on the second active pattern AP2. For example, the first and second recesses RS1 and RS2 may be formed by using the hardmask patterns MP as an etching mask to remove a portion of the stack pattern STP.

The first recesses RS1 may separate the semiconductor layers SL on the first active pattern AP1 into first channel patterns CH1 that are spaced apart from each other in the first direction D1. The second recesses RS2 may separate the semiconductor layers SL on the second active pattern AP2 into second channel patterns CH2 that are spaced apart from each other in the first direction D1. Each of the first and second channel patterns CH1 and CH2 may include the first, second, and third semiconductor patterns SP1, SP2, and SP3.

A dielectric material may replace a portion of the sacrificial layer SAL exposed by the second recess RS2, and thus inner spacers ISP may be formed on opposite sides of the sacrificial layer SAL.

A first lower recess LRS1 may be formed beneath the first recess RS1. A second lower recess LRS2 may be formed beneath the second recess RS2. A backside alignment pattern BA may be formed through a selective epitaxial growth (SEG) process in which the semiconductor substrate 100 is used as a seed, thereby partially or completely filling the first and second lower recesses LRS1 and LRS2. For example, the backside alignment pattern BA may include silicon-germanium (SiGe).

First source/drain patterns SD1 may be formed in the first recesses RS1. The first source/drain patterns SD1 may be formed by performing a selective epitaxial growth (SEG) process in which the backside alignment patterns BA and the first, second, and third semiconductor patterns SP1, SP2, and SP3 on the PMOSFET region PR are used as seeds.

During the formation of the first source/drain pattern SD1, impurities (e.g., boron, gallium, or indium) may be in-situ implanted to allow the first source/drain pattern SD1 to have a p-type conductivity. In some embodiments, after the formation of the first source/drain pattern SD1, the impurities may be implanted into the first source/drain pattern SD1.

For example, the formation of the first source/drain pattern SD1 may include forming a buffer layer BFL to cover, overlap, or be on an inner surface of the first recess RS1, and forming a main layer MAL on the buffer layer BFL. The formation of the buffer layer BFL may include performing a selective epitaxial growth (SEG) process in which the backside alignment pattern BA and the first, second, and third semiconductor patterns SP1, SP2, and SP3 are used as seeds. In this case, a thickness of the buffer layer BFL on a lower portion of the first recess RS1 may be greater than that of the buffer layer BFL on a lateral portion of the first recess RS1. In some embodiments, the buffer layer BFL may have a uniform thickness. The formation of the main layer MAL may include performing a selective epitaxial growth (SEG) process in which the buffer layer BFL is used as a seed. The main layer MAL may be formed to partially or completely fill an unoccupied portion of the first recess RS1.

Second source/drain patterns SD2 may formed in the second recesses RS2. The second source/drain patterns SD2 may be formed by performing a selective epitaxial growth (SEG) process in which the backside alignment patterns BA and the first, second, and third semiconductor patterns SP1, SP2, and SP3 on the NMOSFET region NR are used as seeds.

During the formation of the second source/drain pattern SD2, impurities (e.g., phosphorus, arsenic, or antimony) may be in-situ implanted to allow the second source/drain pattern SD2 to have an n-type conductivity type. In some embodiments, after the formation of the second source/drain pattern SD2, the impurities may be implanted into the second source/drain pattern SD2.

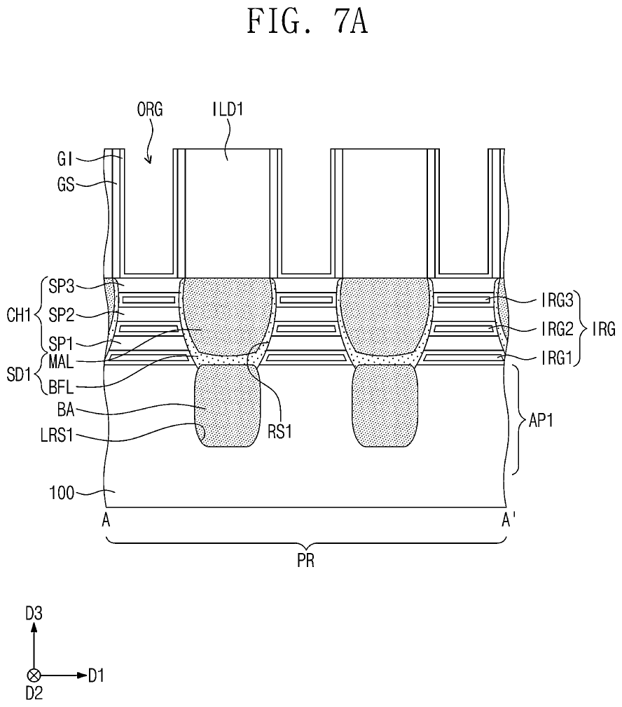

Referring to FIGS. 1, 7A, and 7B, a first interlayer dielectric layer ILD1 may be formed to cover, overlap, or be on the first and second source/drain patterns SD1 and SD2, the hardmask patterns MP, and the gate spacers GS. After that, the first interlayer dielectric layer ILD1 may be removed on to surfaces of the sacrificial patterns PP. In the removal process, the hardmask patterns MP may also be removed, and the sacrificial patterns PP may be exposed.

Thereafter, the exposed sacrificial patterns PP may be removed, and an outer region ORG may be formed on an area where the sacrificial patterns PP are removed. The outer region ORG may outwardly expose the first and second channel patterns CH1 and CH2 and the sacrificial layers SAL.

The exposed sacrificial layers SAL may be selectively removed. In this stage, the first, second, and third semiconductor patterns SP1, SP2, and SP3 may not be removed or may be slightly removed due to a high etch selectivity of the sacrificial layers SAL.

Inner regions IRG may be formed on areas where the sacrificial layers SAL are removed. The inner regions IRG may be formed between the first, second, and third semiconductor patterns SP1, SP2, and SP3. The inner regions IRG may include first, second, and third inner regions IRG1, IRG2, and IRG3 that are spaced apart from each other in a third direction D3.

A gate dielectric pattern GI may be formed in each of the inner regions IRG and the outer region ORG. The gate dielectric pattern GI may be formed to surround each of the first, second, and third semiconductor patterns SP1, SP2, and SP3. The gate dielectric pattern GI may be formed to have a uniform thickness.

Referring back to FIGS. 2A, 2B, 2C, 2D, and 2E, a gate electrode GE may be formed on the gate dielectric pattern GI. The gate electrode GE may include first, second, and third inner electrodes GE1, GE2, and GE3 that are correspondingly formed in the first, second, and third inner regions IRG1, IRG2, and IRG3, and may also include an outer electrode GE4 formed in the outer region ORG. A gate capping pattern GC may be formed on the outer electrode GE4.

A second interlayer dielectric layer ILD2 may be formed on the first interlayer dielectric layer ILD1 and the gate capping pattern GC. Active contacts AC may be formed to penetrate or extend into the first and second interlayer dielectric layers ILD1 and ILD2 and to correspondingly connect with the first and second source/drain patterns SD1 and SD2. Each of the first and second source/drain patterns SD1 and SD2 may include a first pattern T1 that is not connected to the active contact AC and a second pattern T2 that is electrically connected to the active contact AC. The backside alignment pattern BA may include a first backside alignment pattern beneath the first pattern T1 and a second backside alignment pattern beneath the second pattern T2.

A gate contact GT may be formed to penetrate or extend into the second interlayer dielectric layer ILD2 and the gate capping pattern GC and to connect with the gate electrode GE.

The formation of the active contacts AC and the gate contact GT may include forming a barrier pattern BM and a conductive pattern CP on the barrier pattern BM. An ohmic pattern OM may further be formed between the active contact AC and the second pattern T2 of each of the first and second source/drain patterns SD1 and SD2.

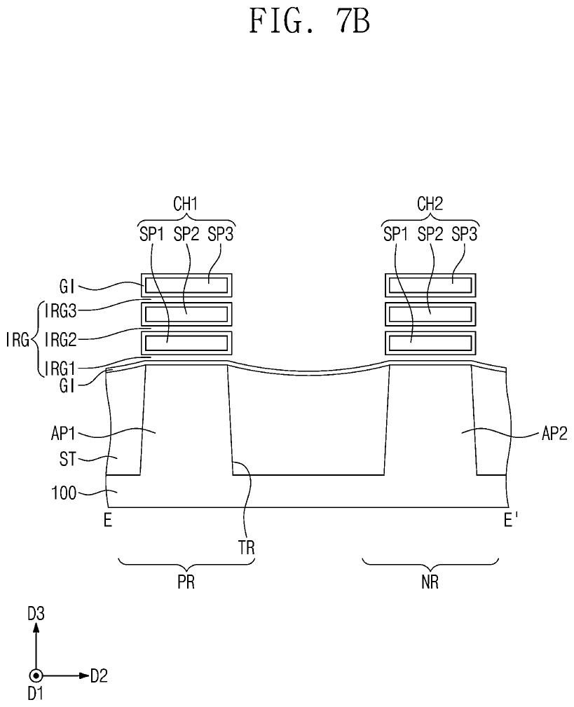

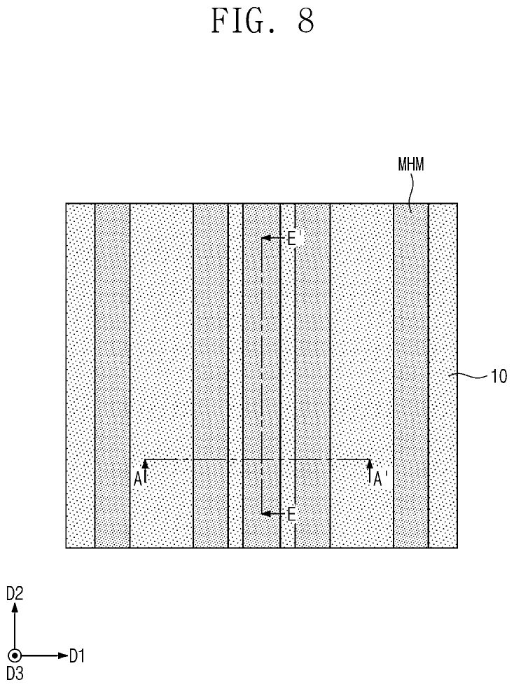

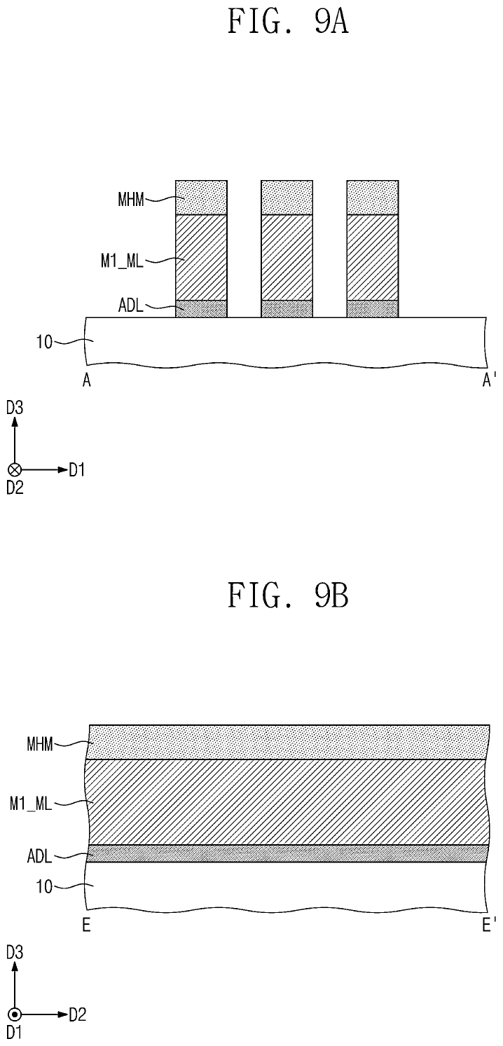

Referring to FIGS. 8, 9A, and 9B, the cell structure 10 discussed above may include a transistor structure including the second interlayer dielectric layer ILD2, the active contacts AC, and the gate contact GT. An adhesion pattern ADL, a first metal line M1_ML, and a first hardmask pattern MHM may be sequentially formed on the cell structure 10. For example, the formation of the adhesion pattern ADL and the first metal line M1_ML may include stacking a metal wiring layer on a metal adhesion layer, forming a first hardmask layer that extends in the first direction D1, and using the first hardmask layer as an etching mask to perform a patterning process.

The metal wiring layer may be formed by performing a physical vapor deposition (PVD) process on the metal adhesion layer. In this case, a grain direction of the metal wiring layer may be the third direction D3. In some embodiments, the metal wiring layer may be formed by a single damascene process.

In the patterning process, the metal adhesion layer, the metal wiring layer, and the first mask layer may be partially removed. Therefore, an adhesion pattern ADL, a first metal line M1_ML, and a first hardmask pattern MHM may be formed stacked on the cell structure 10. The adhesion pattern ADL, the first metal line M1_ML, and the first hardmask pattern MHM may each have a bar shape that extends in the second direction D2.

The adhesion pattern ADL and the first metal lines M1_ML may include a metallic material having a relatively low resistance. The metallic material may include Ru, Rh, Ir, Mo, Cu, Co, or W, for example, Ru. In some embodiments, the metallic material may include an alloy or a metal complex. For example, the metallic material may include RuAl, NiAl, NbB₂, MoB₂, MoW, or any combination thereof.

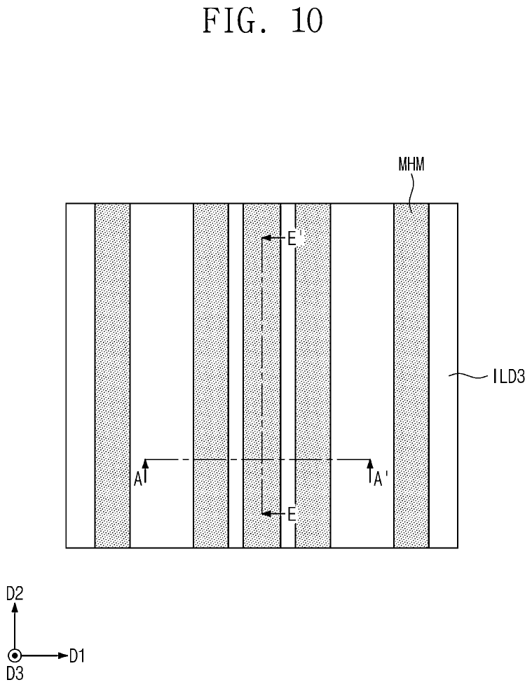

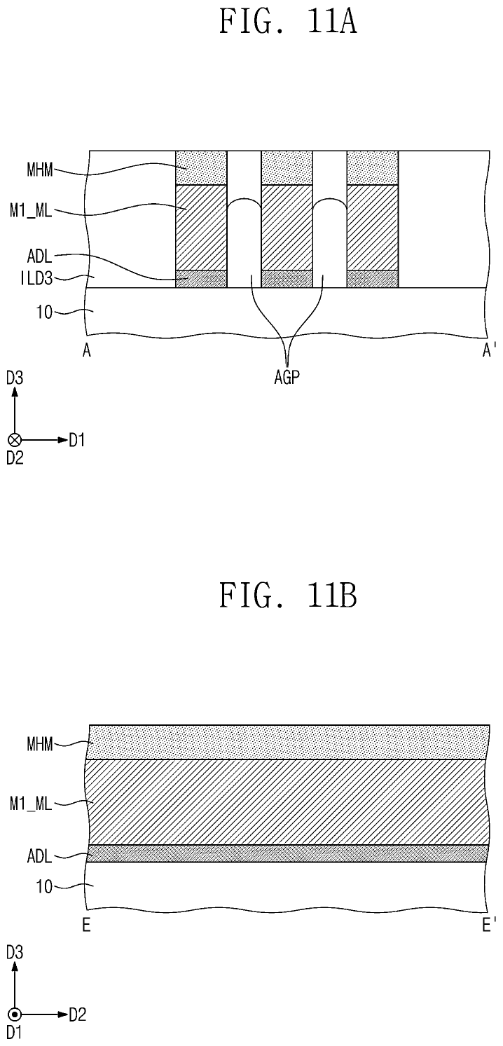

Referring to FIGS. 10, 11A, and 11B, a third interlayer dielectric layer ILD3 may be formed to cover, overlap, or be on the adhesion pattern ADL, the first meal lines M1_ML, and the first hardmask pattern MHM. The formation of the third interlayer dielectric layer ILD3 may include forming a dielectric material on a lateral surface of each of the adhesion pattern ADL and the first metal line M1_ML and a top surface of the first hardmask pattern MHM, and performing a planarization process on the dielectric material. The planarization process may include a chemical mechanical polishing (CMP) process or a wet etching process. The dielectric material may include silicon oxide (SiO₂) or a low-k dielectric material. In this description, the low-k dielectric material may be defined to refer to a material whose dielectric constant is less than that of silicon oxide.

An air gap pattern AGP may be formed when the dielectric material is formed on the lateral surface of each of the adhesion pattern ADL and the first metal line M1_ML and the top surface of the first hardmask pattern MHM. The air gap pattern AGP may be formed between the first metal lines M1_ML. The air gap pattern AGP may have a top surface located at a level in the third direction D3 lower than that of a surface of the first metal line M1_ML. As the air gap pattern AGP is selectively formed, the air gap pattern AGP may not be formed between the first metal line M1_ML (see FIG. 3B).

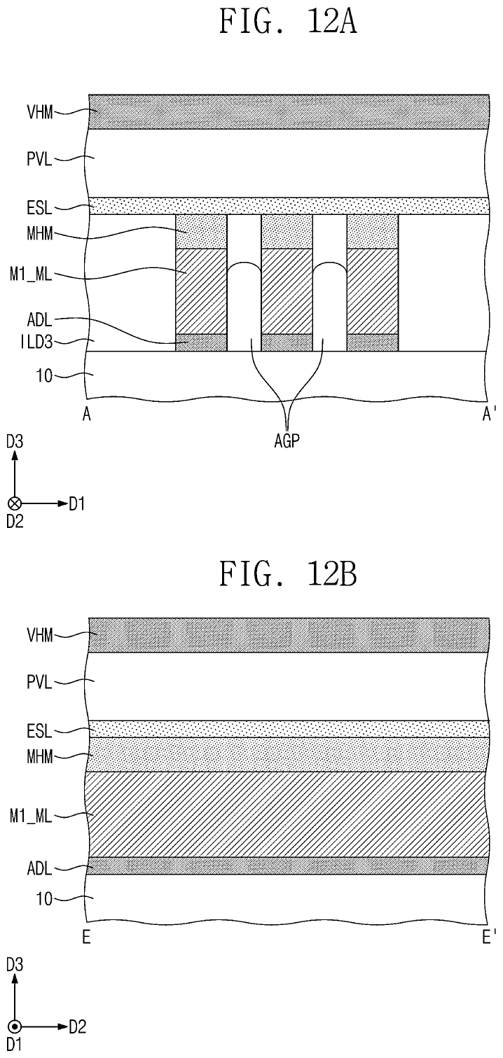

Referring to FIGS. 12A and 12B, an etch stop layer ESL, a preliminary via layer PVL, and a second hardmask layer VHM may be sequentially formed on the third interlayer dielectric layer ILD3 and the first hardmask pattern MHM. A thickness in the third direction D3 of the preliminary via layer PVL may be greater than a thickness in the third direction D3 of the etch stop layer ESL. The etch stop layer ESL and the preliminary via layer PVL may include their materials having an etch selectivity with respect to each other. Thus, in a subsequent removal process of the preliminary via layer PVL, the etch stop layer ESL may not be removed even when the preliminary via layer PVL is removed.

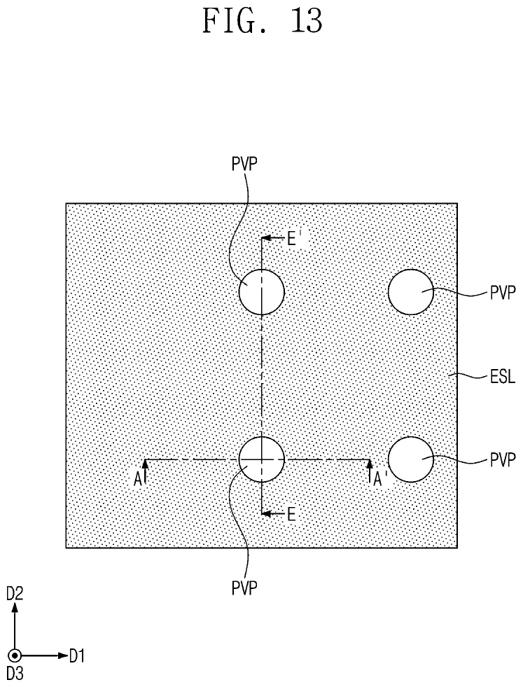

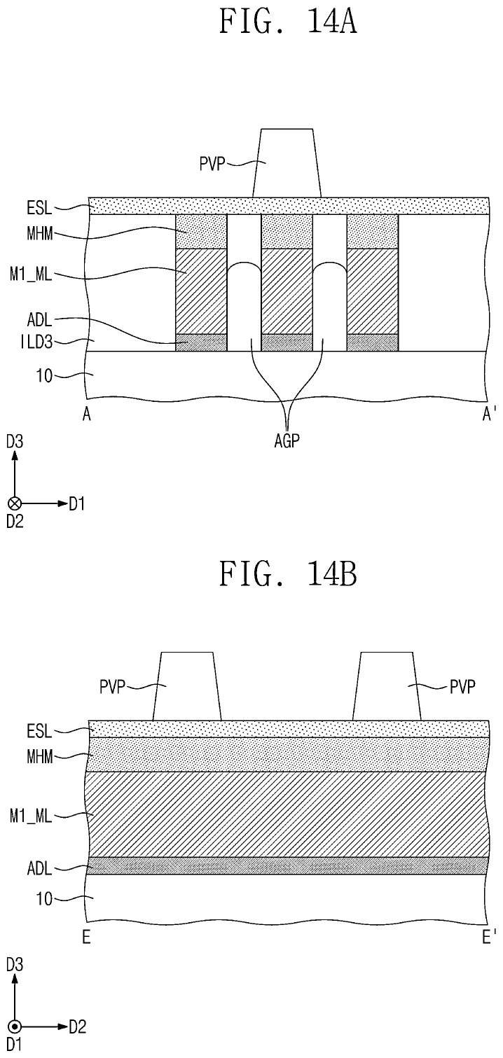

Referring to FIGS. 13, 14A, and 14B, a preliminary via pattern PVP may be formed on the etch stop layer ESL. For example, the formation of the preliminary via pattern PVP may include using the second hardmask layer VHM as an etching mask to perform a patterning process, and removing the second hardmask layer VHM. The patterning process may be a dry etching process, and thus a width of a lower portion of the preliminary via pattern PVP may be greater than a width of an upper portion of the preliminary via pattern PVP. The second hardmask layer VHM may be removed by an ashing process or a wet etching process.

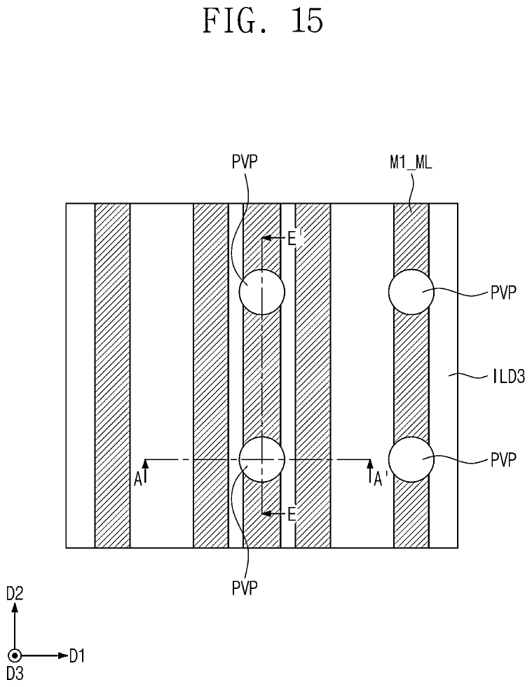

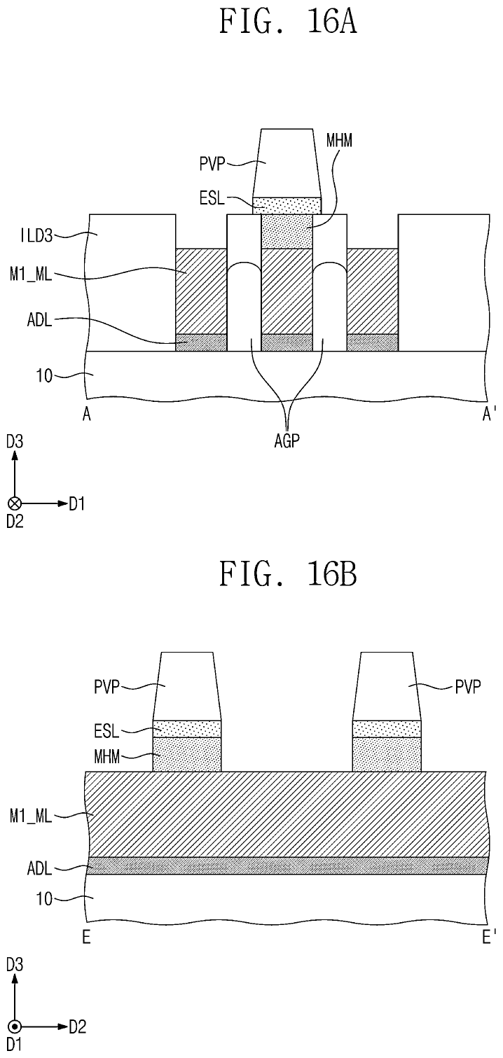

Referring to FIGS. 15, 16A, and 16B, the etch stop layer ESL may undergo an etching process to remove a portion of the etch stop layer ESL and the first hardmask pattern MHM. As the preliminary via pattern PVP and the etch stop layer ESL have their materials having an etch selectivity with respect to each other, even when the etching process is performed, the etch stop layer ESL beneath the preliminary via pattern PVP may remain without being removed. Therefore, the first hardmask pattern MHM may also remain which is disposed beneath the remaining etch stop layer ESL. The removal of the etch stop layer ESL may expose the top surface of each of the first metal lines M1_ML.

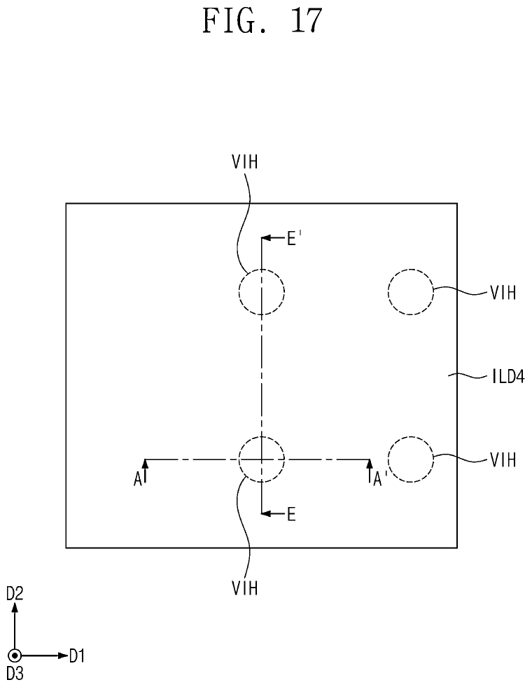

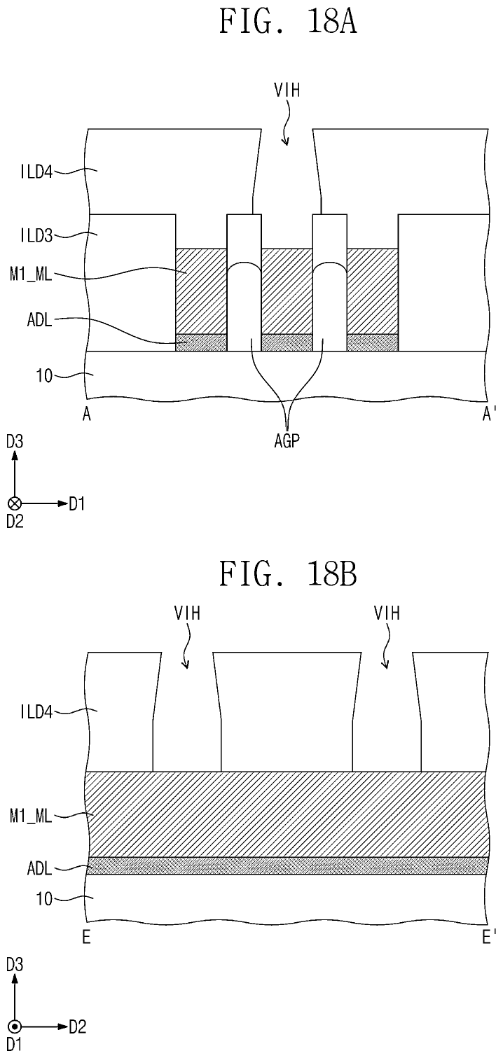

Referring to FIGS. 17, 18A, and 18B, a fourth interlayer dielectric layer ILD4 may be formed to cover, overlap, or be on a top surface and an inner lateral surface of the exposed third interlayer dielectric layer ILD3, the top surface of the first metal line M1_ML, a lateral surface of the etch stop layer ESL, and the preliminary via pattern PVP. The formation of the fourth interlayer dielectric layer ILD4 may include forming a dielectric material on the third interlayer dielectric layer ILD3, the first metal line M1_ML, the first hardmask pattern MHM, the etch stop layer ESL, and the preliminary via pattern PVP, and performing a planarization process on the dielectric material. The planarization process may include a chemical mechanical polishing (CMP) process or a wet etching process. The CMP process may be executed with the preliminary via pattern PVP as a stop layer. For example, the fourth interlayer dielectric layer ILD4 and the preliminary via pattern PVP may have their top surfaces substantially coplanar with each other. The dielectric material may include silicon oxide (SiO₂) or a low-k dielectric material.

The preliminary via pattern PVP may undergo an etching process to form a via hole VIH. A wet etching process may be adopted as the etching process. As the preliminary via pattern PVP, the etch stop layer ESL, and the first hardmask pattern MHM include their materials having an etch selectivity with respect to the fourth interlayer dielectric layer ILD4, the fourth interlayer dielectric layer ILD4 may not be removed during the etching process. The etching process may expose an inner lateral surface of the fourth interlayer dielectric layer ILD4, the inner lateral surface of the third interlayer dielectric layer ILD3, and the top surface of the first metal line M1_ML.

According to the present inventive concepts, the etch stop layer ESL between the third and fourth interlayer dielectric layers ILD3 and ILD4 may be removed to reduce a metallic byproduct residue that remains in a finally formed semiconductor device. As the etch stop layer ESL is removed before the formation of the first metal line M1_ML and the via structure VIST, it may be possible to reduce impurities remaining between the first metal line M1_ML and the via structure VIST. There may thus be a reduction in contact resistance between the first metal line M1_ML and the via structure VIST.

In addition, the etch stop layer ESL may not be included in a three-dimensional field effect transistor according to the present inventive concepts, and thus a parasitic capacitance may be reduced. The reduction in parasitic capacitance may prevent RC delay. Therefore, a semiconductor device may operate at high speeds.

No etch stop layer is included according to some embodiments of the present inventive concepts, and thus the semiconductor device may improve in electrical properties.

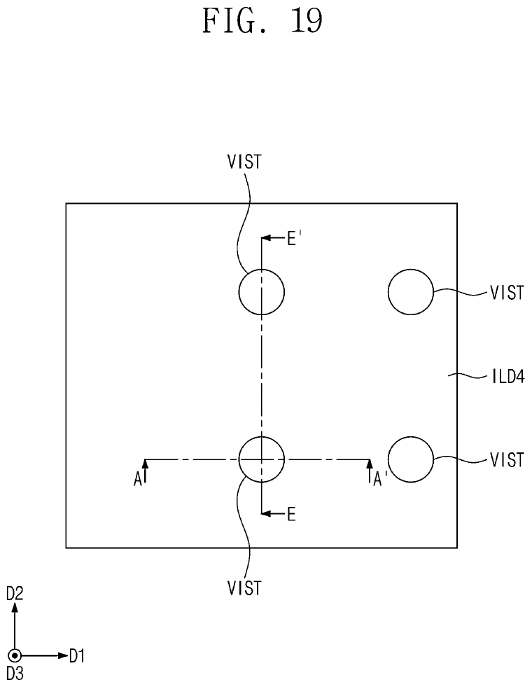

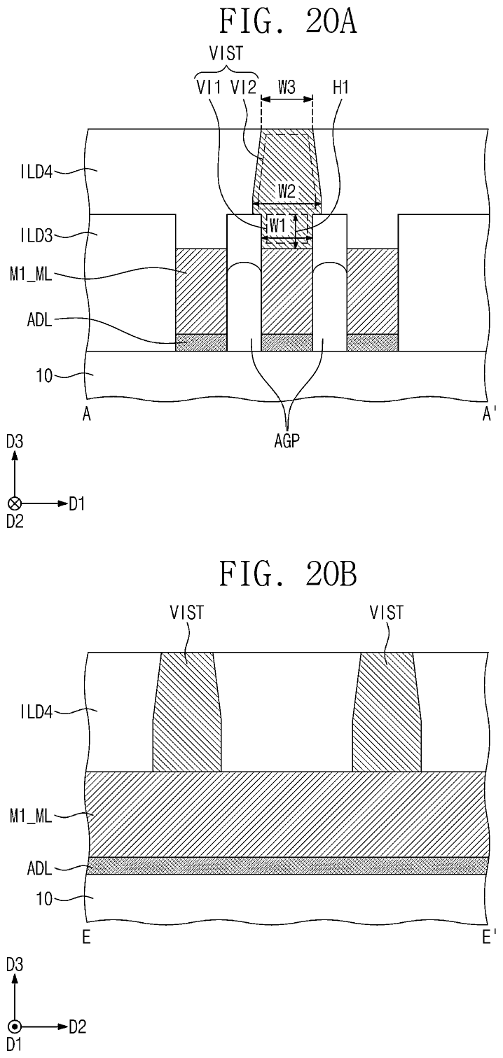

Referring to FIGS. 19, 20A, and 20B, a via structure VIST may be formed to partially or completely fill the exposed via hole VIH of the fourth interlayer dielectric layer ILD4. The via structure VIST may include a first via part VI1 and a second via part VI2 on the first via part VI1. The first via part VI1 may be formed on the inner lateral surface of the third interlayer dielectric layer ILD3 and the top surface of the first metal line M1_ML. The second via part VI2 may be formed on the inner lateral surface of the fourth interlayer dielectric layer ILD4, the top surface of the third interlayer dielectric layer ILD3, and the first via part VI1.

The via structure VIST may be formed by performing a chemical vapor deposition (CVD) process on the via hole VIH. In this case, the via structure VIST may have various grain directions. For example, the grain direction of the via structure VIST may be the first direction D1, the second direction D2, the third direction D3, a direction that intersects the first and second directions D1 and D2, or a direction that intersects the first and third directions D1 and D3. As the grain direction of the via structure VIST is different from that of the first metal line M1_ML, an interface may be included between the via structure VIST and the first metal line M1_ML.

The via structure VIST may include a metallic material having a relatively low resistance. The metallic material may include Ru, Rh, Ir, Mo, Cu, Co, or W, for example, Ru. In some embodiments, the metallic material may include an alloy or a metal complex. For example, the metallic material may include RuAl, NiAl, NbB₂, MoB₂, MoW, or any combination thereof.

According to the present inventive concepts, the first metal line M1_ML and the via structure VIST may be formed to avoid misalignment with each other, and thus a step height greater than a target value may be achieved between the first metal line M1_ML and the via structure VIST. The step height may be the same as the first height H1 of the first via part VI1 of the via structure VIST. As the first metal line M1_ML and the via structure VIST are vertically aligned through the first via part VI1 of the via structure VIST, a time-dependent dielectric breakdown (TDDB) failure may be reduced.

A three-dimensional field effect transistor according to the present inventive concepts may be configured such that the first via part VI1 and the second via part VI2 may be formed in a bottom-up manner to reduce physical or chemical damage to the first metal line M1_ML. For example, a pre-cleaning process may be performed on the first metal line M1_ML before the first via part VI1 is formed, it may be possible to prevent pattern defects occurring when the via structure VIST is formed.

The first metal line M1_ML and the via structure VIST may be formed according to some embodiments of the present inventive concepts, and as a result, a semiconductor device may improve in reliability.

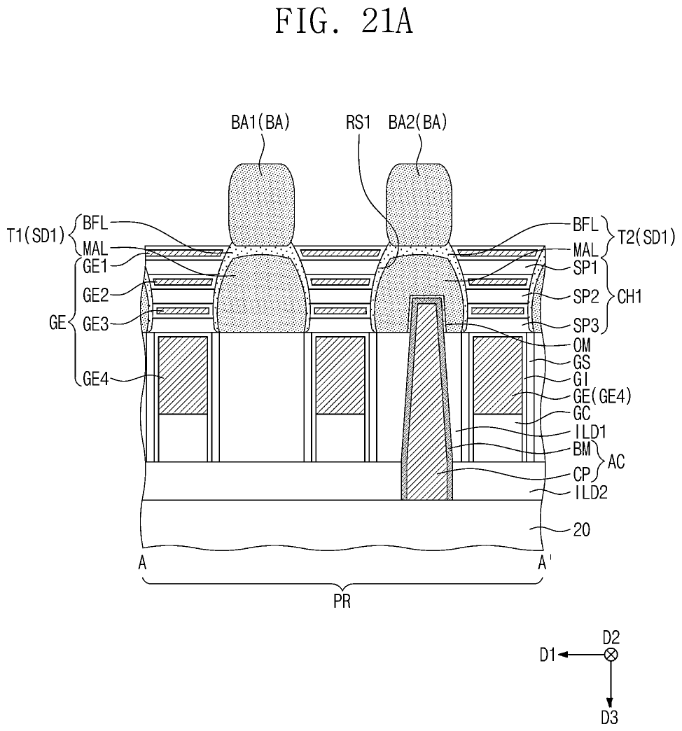

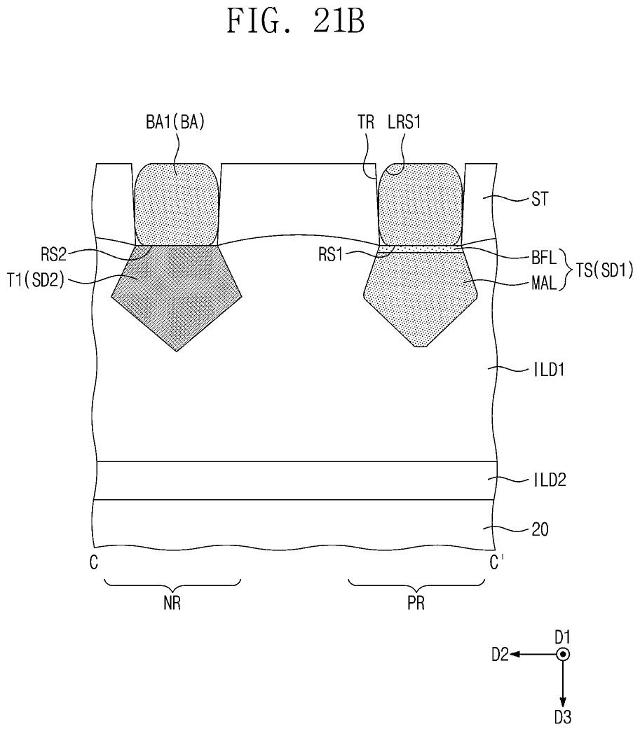

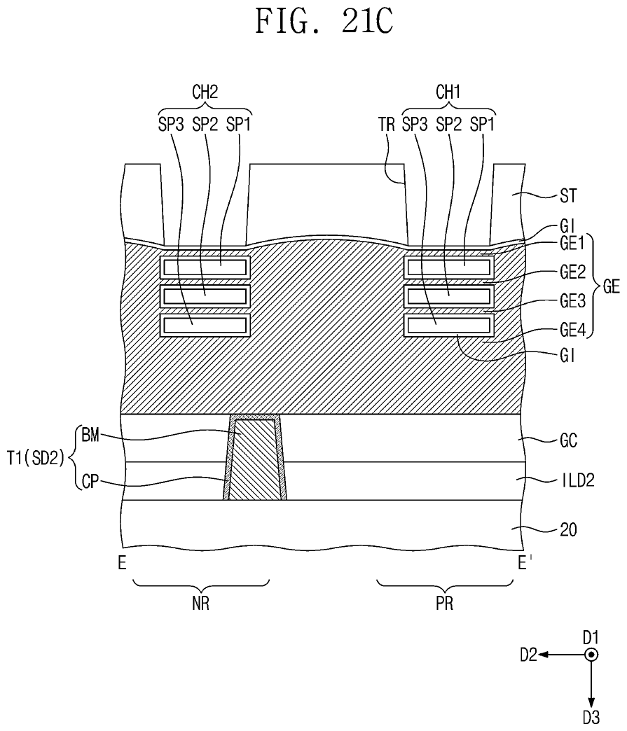

After the termination of a back-end-of-line (BEOL) process, the semiconductor substrate 100 discussed with reference to FIGS. 4A and 4B may be flipped upside down. As a semiconductor substrate (see 100 of FIG. 4A) is flipped upside down, terms “top surface” and “upper portion” in the following explanation with reference to FIGS. 21A, 21B, 21C, 22A, 22B, 22C, 23A, and 23B may respectively refer to “bottom surface” and “lower portion” from the point of view of the semiconductor device fabricated as discussed in FIGS. 2A, 2B, 2C, 2D, and 2E, and terms “bottom surface” and “lower portion” in the following explanation with reference to FIGS. 21A, 21B, 21C, 22A, 22B, 22C, 23A, and 23B may respectively refer to “top surface” and “upper portion” from the point of view of the semiconductor device fabricated as discussed in FIGS. 2A, 2B, 2C, 2D, and 2E.

Referring back to FIGS. 21A, 21B, and 21C, after the termination of a back-end-of-line (BEOL) process, the semiconductor substrate 100 may be overturned to expose a bottom surface of the semiconductor substrate 100. The exposed semiconductor substrate 100 may be completely removed. In this case, the completion of the BEOL process may form a wiring structure 20 on the second interlayer dielectric layer ILD2, and the wiring structure 20 may be vertically downwardly directed. The wiring structure 20 may include the third interlayer dielectric layer ILD3, the adhesion pattern ADL, the first metal lines M1_ML, the air gap pattern AGP, the fourth interlayer dielectric layer ILD4, and the via structure VIST that are discussed above with reference to FIGS. 8, 9A, 9B, 10, 11A, 11B, 12A, 12B, 13, 14A, 14B, 15, 16A, 16B, 17, 18A, 18B, 19, 20A, and 20B.

In an embodiment of the present inventive concepts, the removal of the semiconductor substrate 100 may include allowing the bottom surface of the semiconductor substrate 100 to undergo a planarization process to reduce a thickness of the semiconductor substrate 100, allowing the semiconductor substrate 100 to undergo a cleaning process to selectively remove silicon (Si), and performing an etching process to selectively remove silicon (Si) in the first and second active patterns AP1 and AP2. The cleaning process may continue until the device isolation pattern ST is exposed. The etching process may be a dry etching process or a wet etching process. After the etching process is performed, the backside alignment pattern BA may remain.

The removal of the semiconductor substrate 100 may form a first backside trench on an area where the first active pattern AP1 is present in a previous step. The removal of the semiconductor substrate 100 may form a second backside trench on an area where the second active pattern AP2 is present in a previous step (see FIGS. 21B and 21C).

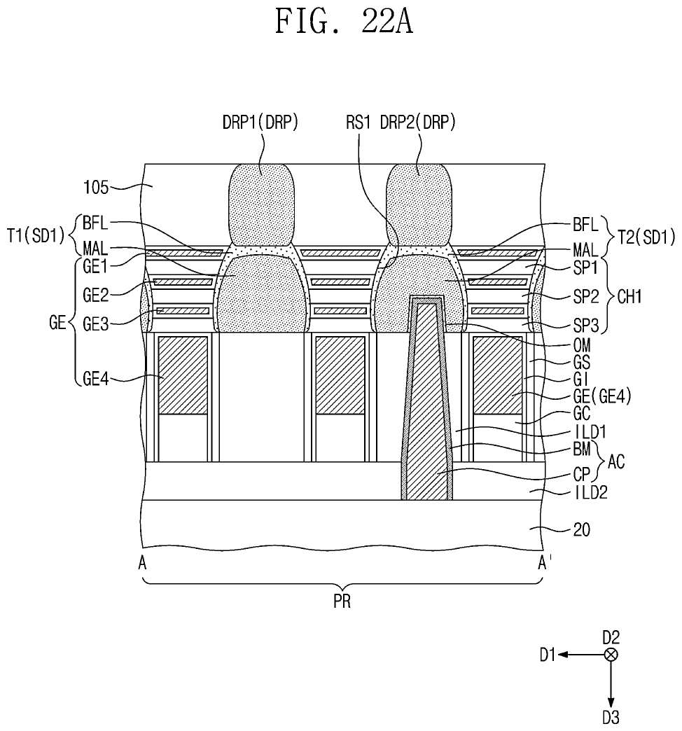

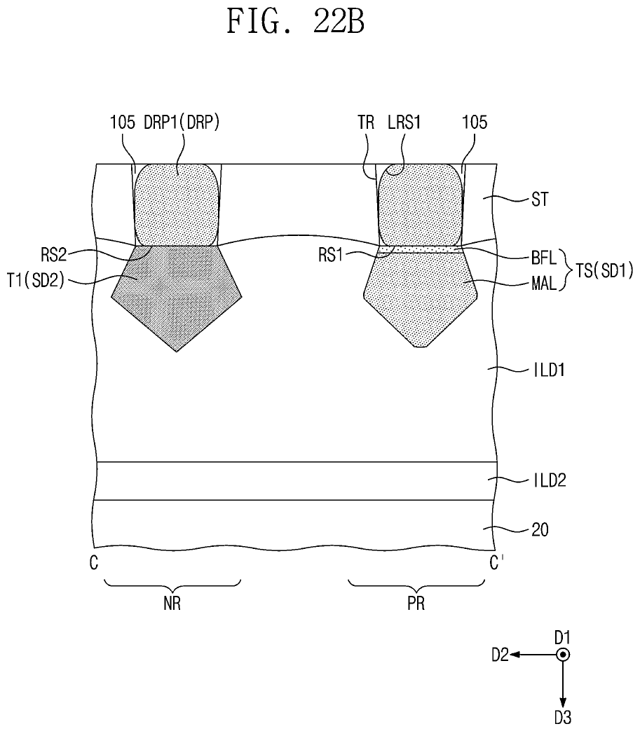

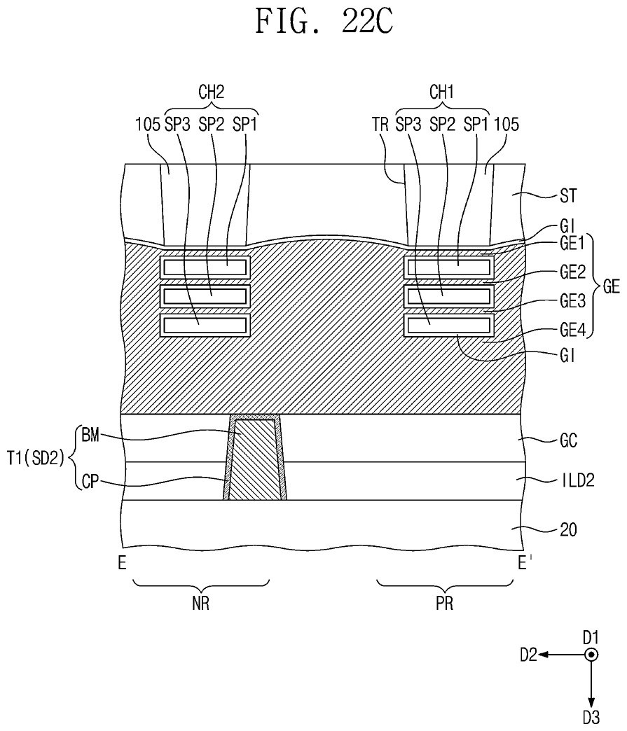

Referring to FIGS. 1, 22A, 22B, and 22C, a substrate 105 may be formed to partially or completely fill areas from which are removed the semiconductor substrate (see 100 of FIG. 4A) and the first and second active patterns (see AP1 and AP2 of FIG. 4A). The substrate 105 may be formed to partially or completely fill the first and second backside trenches. The substrate 105 may be formed by partially or completely filling a dielectric material to a level higher than that of the semiconductor substrate (see 100 of FIG. 4A). The substrate 105 may be formed to cover, overlap, or be on the backside alignment pattern BA. Afterwards, the substrate 105 may undergo a chemical mechanical polishing (CMP) process performed with the backside alignment pattern BA as a stop layer. The substrate 105 may have a top surface substantially coplanar with that of the backside alignment pattern BA.

The backside alignment pattern BA may be removed, and a lower dielectric pattern DRP may be formed. The formation of the lower dielectric pattern DRP may include performing a cleaning process to selectively remove the backside alignment pattern BA in the substrate 105, and performing a deposition process to partially or completely fill a recess formed by the cleaning process. The cleaning process may be a wet etching process that selectively removes silicon-germanium. The deposition process may be a chemical vapor deposition (CVD) process, a low pressure CVD process, a physical vapor deposition (PVD) process, or atomic layer deposition (ALD) process.

The lower dielectric pattern DRP may include a first lower dielectric pattern DRP1 on the first pattern T1 of each of the source/drain patterns SD1 and SD2, and a second lower dielectric pattern DRP2 on the first pattern T1 of each of the source/drain patterns SD1 and SD2. The lower dielectric pattern DRP may include a dielectric material. For example, the dielectric material may include at least one selected from a silicon oxide (SiO₂) layer, a silicon nitride (SiN) layer, an aluminum oxide (Al₂O₃) layer, and/or an aluminum nitride (AlN) layer.

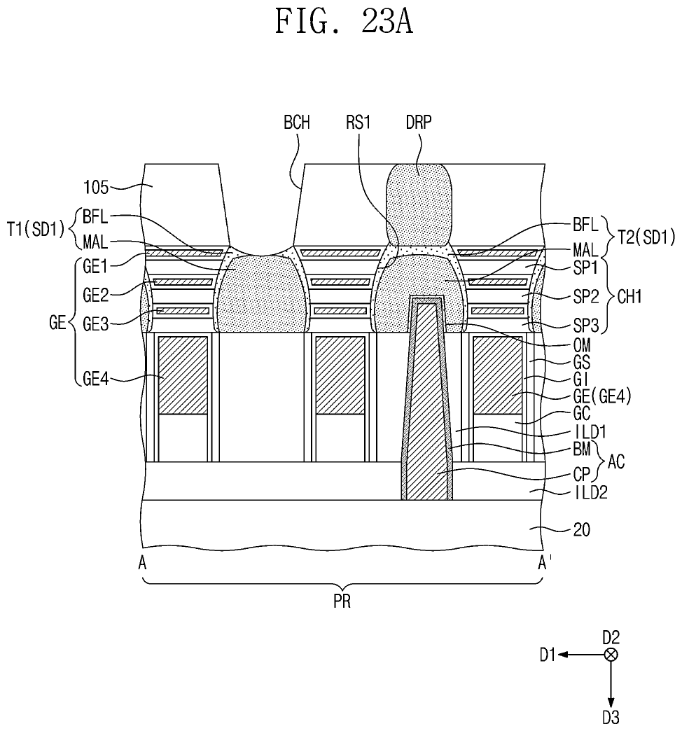

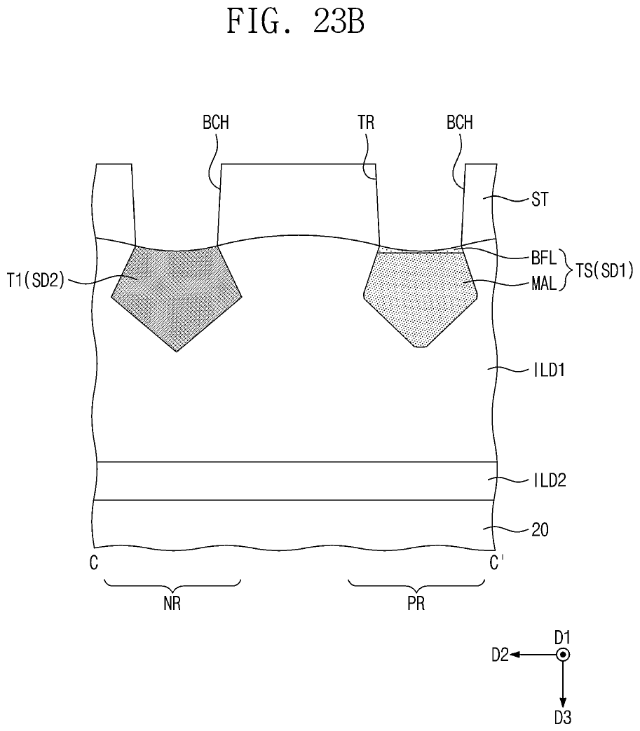

Referring to FIGS. 1, 23A, and 23B, a backside contact hole BCH may be formed on the first pattern T1, penetrating the substrate 105. The backside contact hole BCH may be formed to recess an upper portion of the first pattern T1 of each of the first and second source/drain patterns SD1 and SD2.

The formation of the backside contact hole BCH may include forming a hardmask pattern on the substrate 105, using the hardmask pattern to perform a dry etching process on the first lower dielectric pattern DRP1, and removing the hardmask pattern. In this case, the lower dielectric pattern DRP on the second pattern T2 may remain without being removed.

Referring back to FIGS. 1, 2A, 2B, 2C, 2D, and 2E, a backside conductive structure BCS may be formed to partially or completely fill the backside contact hole BCH. The formation of the backside conductive structure BCS may include forming a backside barrier pattern BBM that conformally covers, overlaps, or is on an inner sidewall and an inner bottom surface of the backside contact hole BCH, and forming on the backside barrier pattern BBM a backside conductive pattern BT that partially or completely fills the backside contact hole BCH. The backside conductive pattern BT may be formed through a single process, and thus no interface may be separately formed in the backside conductive pattern BT. Thus, the backside conductive pattern BT may have a relatively low electrical resistance, and a semiconductor device may improve in electrical properties. Afterwards, a power delivery network layer PDN may be formed on the bottom surface of the substrate 105.

A three-dimensional field effect transistor according to the present inventive concepts may be configured such that a metal line and a via structure may be formed to avoid misalignment with each other to achieve a step height greater than a target value between the metal line and the via structure. For example, it may be possible to reduce a time-dependent dielectric breakdown due to misalignment between the metal line and the via structure.

Moreover, in the three-dimensional field effect transistor according to the present inventive concepts, the via structure may be formed in a bottom-up manner, and thus it may be possible to reduce physical or chemical damage to the metal line. For example, a pre-cleaning process may be performed on the metal line before the formation of the via structure, and thus the via structure may be prevented from pattern defects. As a result, the semiconductor device may improve in reliability.

A three-dimensional field effect transistor according to the present inventive concepts may be configured such that a metal line may be formed by performing a positive etching process to reduce metallic byproduct residues occurring from an etch stop layer. Thus, impurities remaining between the metal line and a via structure may be reduced to decrease a contact resistance.

In addition, the three-dimensional field effect transistor according to the present inventive concepts may be configured such that no etch stop layer may be formed and thus a parasitic capacitance may be reduced. Accordingly, a semiconductor device may improve in electrical properties.

Although the present inventive concepts have been described in connection with the some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive. As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device, comprising:
a substrate; and
a wiring structure on the substrate,
wherein the wiring structure comprises:
a first interlayer dielectric layer;
a first metal line that extends into the first interlayer dielectric layer; and
a second interlayer dielectric layer on the first interlayer dielectric layer;
a via structure that extends into the second interlayer dielectric layer and is electrically connected to the first metal line,
wherein the via structure comprises:
a first via part; and
a second via part on the first via part, and
wherein a first width of the first via part is less than a second width of the second via part.

2. The semiconductor device of claim 1, wherein the second width of the second via part decreases in a direction away from the substrate.

3. The semiconductor device of claim 1, wherein the first via part comprises a first sidewall and a second sidewall that face each other in a first direction,
wherein the first and second sidewalls are substantially parallel in a second direction that intersects the first direction.

4. The semiconductor device of claim 1, wherein the second via part comprises a third sidewall and a fourth sidewall,
wherein the third sidewall has a positive slope, and
wherein the fourth sidewall has a negative slope.

5. The semiconductor device of claim 1, wherein the first via part has a first height in a direction perpendicular to the substrate,
wherein the first metal line has a second height in the direction perpendicular to the substrate, and
wherein the second height is greater than the first height.

6. The semiconductor device of claim 5, wherein the first height is in a range of 2 nm to 9 nm.

7. The semiconductor device of claim 1, further comprising:
an adhesion pattern between the substrate and the first metal line,
wherein the adhesion pattern comprises a metallic material that is same as a metallic material of the first metal line.

8. The semiconductor device of claim 1, wherein a lowermost surface of the second interlayer dielectric layer is a first distance from the substrate that is less than a second distance of an uppermost surface of the first interlayer dielectric layer from the substrate.

9. The semiconductor device of claim 1, wherein the first metal line and the via structure each comprise a metallic material, and
wherein the metallic material includes Ru, Rh, Ir, Mo, Cu, Co, W, RuAl, NiAl, NbB₂, MoB₂, MoW, or any combination thereof.

10. The semiconductor device of claim 9, further comprising:
an interface between the first metal line and the via structure,
wherein the first metal line and the via structure include Ru.

11. A semiconductor device, comprising:
a substrate;
a channel pattern on the substrate;
a source/drain pattern electrically connected to the channel pattern;
a gate electrode on the channel pattern;
a first interlayer dielectric layer on the source/drain pattern;
a second interlayer dielectric layer on the first interlayer dielectric layer and the gate electrode;
an active contact that extends into the first and second interlayer dielectric layers and electrically connects with the source/drain pattern;
a third interlayer dielectric layer on the second interlayer dielectric layer, wherein a plurality of first metal lines extends into the third interlayer dielectric layer, wherein a first metal line of the first metal lines electrically connects to the active contact, and wherein an air gap pattern is between adjacent ones of the plurality of first metal lines; and
a fourth interlayer dielectric layer on the third interlayer dielectric layer, the fourth interlayer dielectric layer including a via structure that is electrically connected to a second one of the first metal lines,
wherein an uppermost surface of the air gap pattern is a first distance from the substrate that is less than a second distance from a lowermost surface of the fourth interlayer dielectric layer to the substrate.

12. The semiconductor device of claim 11, wherein the air gap pattern is is adjacent ones of the first metal lines, the second interlayer dielectric layer, and the third interlayer dielectric layer.

13. The semiconductor device of claim 11, wherein the air gap pattern comprises a void or a seam.

14. The semiconductor device of claim 11, wherein a lowermost surface of the via structure is a third distance from the substrate, and
wherein the third distance is greater than the first distance.

15. The semiconductor device of claim 14, wherein the third distance of the lowermost surface of the via structure to the substrate is equal to the second distance of the lowermost surface of the fourth interlayer dielectric layer to the substrate.

16. The semiconductor device of claim 11, further comprising:
an adhesion pattern between the first metal line and the active contact,
wherein a sum of a height of the first metal line and a height of the adhesion pattern is greater than a height of the air gap pattern.

17. The semiconductor device of claim 11, wherein the via structure comprises:
a first via part on the first metal line; and
a second via part on the first via part,
wherein the first via part has a first line-width,
wherein the second via part has a second line-width of a lower portion of the second via part and a third line-width of an upper portion of the second via part, and
wherein the second line-width is greater than the first line-width and the third line-width.

18. The semiconductor device of claim 17, wherein the third line-width is greater than the first line-width.

19. A semiconductor device, comprising:
a substrate;
a power delivery network layer on a bottom surface of the substrate, the power delivery network layer including a lower line;
a plurality of source/drain patterns on the substrate, the source/drain patterns including a first pattern and a second pattern that are spaced apart from each other in a first direction;
a channel pattern on a lateral surface of the source/drain pattern, the channel pattern including a plurality of semiconductor patterns that are stacked spaced apart from each other in a second direction that intersects the first direction;
a gate electrode including a first inner electrode, a second inner electrode, and a third inner electrode between neighboring ones of the plurality of semiconductor patterns and an outer electrode on an uppermost one of the plurality of semiconductor patterns;
a gate dielectric pattern on the gate electrode;
a gate capping pattern on a top surface of the outer electrode;
a first interlayer dielectric layer on the source/drain patterns;
a second interlayer dielectric layer on the first interlayer dielectric layer and the gate capping pattern;
an active contact that extends into the first and second interlayer dielectric layers and electrically connects with the second pattern of the source/drain pattern;
a third interlayer dielectric layer on the second interlayer dielectric layer, the third interlayer dielectric layer including a first metal line electrically connected to the active contact, an adhesion pattern between the active contact and the first metal line, and an air gap pattern between adjacent ones of a plurality of first metal lines that comprises the first metal line;
a fourth interlayer dielectric layer on the third interlayer dielectric layer, the fourth interlayer dielectric layer including a via structure electrically connected to a second metal line of the plurality of metal lines;
a backside conductive structure that extends into the substrate and electrically connects the first pattern of the source/drain patterns to the power delivery network layer; and
a lower dielectric pattern on the second pattern of the source/drain patterns,
wherein the via structure comprises:
a first via part on the second metal line; and
a second via part on the first via part,
wherein the second via part has a tapered shape that extends away from the substrate.

20. The semiconductor device of claim 19, wherein the second via part overlaps the first via part and a portion of the air gap pattern in the second direction.
